(19) United States
(12) Patent Application Publication
(10) Pub. No.: US 2025/0107407 A1
(43) Pub. Date: Mar. 27, 2025

(54) DISPLAY DEVICE

(71) Applicant: Samsung Display Co., LTD., Yongin-si (KR)

(72) Inventors: Soo Dong KIM, Yongin-si (KR); Jung Hwan YI, Yongin-si (KR); Ji Eun KO, Yongin-si (KR); Rae Young KIM, Yongin-si (KR); Yo Han KIM, Yongin-si (KR); Je Won YOO, Yongin-si (KR); Su Min JUNG, Yongin-si (KR); Hye Young HAN, Yongin-si (KR)

(73) Assignee: Samsung Display Co., LTD., Yongin-si (KR)

(21) Appl. No.: 18/641,724

(22) Filed: Apr. 22, 2024

(30) Foreign Application Priority Data
Sep. 27, 2023 (KR) 10-2023-0130978

(51) Int. Cl. H10K 59/80; H10K 59/35

(52) U.S. Cl. CPC H10K 59/875; H10K 59/35

(57) ABSTRACT

A display device that includes a light emitting element layer disposed on a substrate, a thin-film encapsulation layer disposed on the light emitting element layer, a wavelength conversion layer disposed on the thin-film encapsulation layer and including a bank which defines light emitting areas and a non-light emitting area, a dam structure disposed on the wavelength conversion layer and overlapping at least one of the light emitting areas, a filling layer disposed on the wavelength conversion layer and disposed between portions of the dam structure, a color filter layer disposed on the dam structure, and a counter substrate disposed on the color filter layer, wherein the filling layer overlaps ones of the light emitting areas not overlapping the dam structure.

### CROSS-REFERENCE TO RELATED APPLICATIONS

This application claims priority under 35 U.S.C. § 119 from Korean Patent Application No. 10-2023-0130978 filed on Sep. 27, 2023 in the Korean Intellectual Property Office, the entire contents of which are incorporated herein by reference.

### BACKGROUND

### 1. Technical Field

The disclosure relates to a display device.

### 2. Description of the Related Art

As the information society develops, demands for display devices for displaying images are increasing in various forms. For example, display devices are applied to various electronic devices such as smartphones, digital cameras, notebook computers, navigation devices, and smart televisions.

The display devices may be flat panel display devices such as liquid crystal display devices, field emission display devices, and light emitting display devices. The light emitting display devices may include an organic light emitting display device including an organic light emitting element, an inorganic light emitting display device including an inorganic light emitting element such as an inorganic semiconductor, and a micro-light emitting display device including a micro-light emitting element.

An organic light emitting element may include two electrodes facing each other and a light emitting layer disposed between them. The light emitting layer may receive electrons and holes from the two electrodes, recombine them to generate excitons, and emit light as the generated excitons change from an excited state to a ground state.

Since organic light emitting display devices including organic light emitting elements do not need a light source such as a backlight part, they may be low in power consumption, can be made lightweight and thin, and have a wide viewing angle, high luminance and contrast, and fast response speed. Due to these high-quality characteristics, the organic emitting display devices are drawing attention as next-generation display devices.

### SUMMARY

Aspects of the disclosure provide a display device with improved front side luminance ratio and white efficiency.

However, aspects of the disclosure may not be restricted to the one set forth herein. The above and other aspects of the disclosure will become more apparent to one of ordinary skill in the art to which the disclosure pertains by referencing the detailed description of the disclosure given below.

According to an aspect of the disclosure, a display device may comprise a light emitting element layer disposed on a substrate, a thin-film encapsulation layer disposed on the light emitting element layer, a wavelength conversion layer disposed on the thin-film encapsulation layer and comprising a bank which defines a plurality of light emitting areas and a non-light emitting area, a dam structure disposed on the wavelength conversion layer and overlapping at least one of the plurality of light emitting areas, a filling layer disposed on the wavelength conversion layer and disposed between portions of the dam structure, a color filter layer disposed on the dam structure, and a counter substrate disposed on the color filter layer, wherein the filling layer overlaps ones of the plurality of light emitting areas not overlapping the dam structure.

In an embodiment, the at least one of the plurality of light emitting areas overlapping the dam structure may have a light conversion rate of about 50% or less in the wavelength conversion layer.

In an embodiment, the plurality of light emitting areas may comprise a first light emitting area which emits blue light, a second light emitting area which emits red light and a third light emitting area which emits green light, and the dam structure may overlap the first light emitting area.

In an embodiment, the filling layer may overlap the second light emitting area and the third light emitting area.

In an embodiment, the dam structure may not overlap the non-light emitting area.

In an embodiment, the dam structure may overlap portions of the non-light emitting area adjacent to the at least one of the plurality of light emitting areas overlapping the dam structure and does not overlap portions of the non-light emitting area spaced apart from the at least one of the plurality of light emitting areas overlapping the dam structure.

In an embodiment, the dam structure may overlap the non-light emitting area.

In an embodiment, a refractive index of the dam structure may be greater than that of the filling layer.

In an embodiment, a refractive index of the dam structure may be in a range of about 1.5 to about 2.

In an embodiment, a refractive index of the filling layer may be in a range of about 1.05 to about 1.4.

In an embodiment, a thickness of the dam structure may be less than or equal to that of the filling layer.

In an embodiment, a thickness of the dam structure and a thickness of the filling layer may each be in a range of about 0.1 to about 4.5 um.

In an embodiment, the color filter layer may comprise a plurality of color filters and an overcoat layer covering the plurality of color filters, and the dam structure and the filling layer may contact the overcoat layer.

In an embodiment, the wavelength conversion layer may comprise a light transmission pattern overlapping the dam structure, and first and second wavelength conversion patterns overlapping the filling layer.

In an embodiment, the filling layer may overlap the plurality of light emitting areas and may cover the dam structure.

In an embodiment, the filling layer may contact the color filter layer, and the dam structure may be spaced apart from the color filter layer.

In an embodiment, the filling layer may comprise an arrangement selected from a plurality of filling particles dispersed in a filling resin, a silicone compound, and at least one of a vacuum, nitrogen gas and an inert gas.

According to an aspect of the disclosure, a display device may comprise a light emitting element layer disposed on a substrate, a thin-film encapsulation layer disposed on the light emitting element layer, a wavelength conversion layer disposed on the thin-film encapsulation layer and comprising a bank which defines a plurality of light emitting areas and a non-light emitting area, a dam structure disposed on the wavelength conversion layer and overlapping ones of the plurality of light emitting areas with a light conversion rate of 50% or less in the wavelength conversion layer, a filling layer disposed on the wavelength conversion layer and disposed between portions of the dam structure, a color filter layer disposed on the dam structure, and a counter substrate disposed on the color filter layer.

In an embodiment, the plurality of light emitting areas may comprise a first light emitting area which emits blue light, a second light emitting area which emits red light and a third light emitting area which emits green light, and the dam structure may overlap the first light emitting area.

In an embodiment, the plurality of light emitting areas may comprise a first light emitting area which emits blue light, a second light emitting area which emits red light, a third light emitting area which emits green light and a fourth light emitting area which emits white light, and the dam structure may overlap the fourth light emitting area.

In an embodiment, a taper angle of the dam structure may be in a range of about 20 to about 170 degrees.

In an embodiment, the area of an upper surface of the dam structure may be in a range of about 60 to about 1000% of the area of a lower surface of the dam structure.

According to an aspect of the disclosure, a display device may comprise a light emitting element layer disposed on a substrate, a thin-film encapsulation layer disposed on the light emitting element layer, a wavelength conversion layer disposed on the thin-film encapsulation layer, a filling layer disposed on the wavelength conversion layer, a color filter layer disposed on the filling layer, and a counter substrate disposed on the color filter layer, wherein a refractive index of the filling layer may be in a range of about 1.05 to about 1.4, and a thickness of the filling layer may be in a range of about 0.1 to about 4.5 um.

In an embodiment, the filling layer may be disposed between the wavelength conversion layer and the color filter layer and may contact each of the wavelength conversion layer and the color filter layer.

In an embodiment, the filling layer may comprise a silicone compound or a plurality of filling particles dispersed in a filling resin.

A display device according to an embodiment may include a filling layer having a low refractive index between a wavelength conversion layer and a color filter layer. Therefore, it is possible to increase the front side luminance ratio of the display device and prevent a reduction in front luminance efficiency.

A display device according to an embodiment may include a dam structure having a high refractive index in a light emitting area with a light conversion rate of about 50% or less.

Therefore, it may be possible to improve the front side luminance ratio of the light emitting area and maintain a gap between a substrate and a counter substrate.

However, the effects of the disclosure may not be restricted to the one set forth herein. The above and other effects of the disclosure will become more apparent to one of daily skill in the art to which the disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings in which:

FIG. 1 is a plan view of a display device according to an embodiment;

FIG. 2 is a schematic layout view illustrating lines included in the display device according to the embodiment;

FIG. 3 is a schematic diagram of an equivalent circuit of a subpixel according to an embodiment;

FIG. 4 is a schematic cross-sectional view of the display device according to the embodiment;

FIG. 5 is a schematic cross-sectional view of the display device according to the embodiment;

FIG. 6 is a schematic cross-sectional view of a filling layer of the display device according to the embodiment;

FIGS. 7 through 9 are schematic cross-sectional views illustrating each process in a method of manufacturing a display device according to an embodiment;

FIG. 10 is a schematic cross-sectional view of a display device according to an embodiment;

FIG. 11 is a plan view illustrating each light emitting area of the display device of FIG. 10;

FIG. 12 is a schematic cross-sectional view of an example of a dam structure according to an embodiment;

FIG. 13 is a schematic cross-sectional view of another example of the dam structure according to the embodiment;

FIG. 14 is a schematic cross-sectional view of another example of the dam structure according to the embodiment;

FIGS. 15 and 16 illustrate other examples of the display device according to the embodiment of FIG. 10;

FIG. 17 is a schematic cross-sectional view of a display device according to an embodiment;

FIG. 18 is a schematic cross-sectional view of a display device according to an embodiment;

FIG. 19 is a plan view illustrating light emitting areas of the display device of FIG. 18;

FIG. 20 is a graph illustrating white efficiency and front side luminance ratio with respect to the refractive index of a filling layer;

FIG. 21 is a graph illustrating BT2020 coverage with respect to the refractive index and thickness of the filling layer;

FIG. 22 is a graph illustrating the front side luminance ratio of each light emitting area with respect to angle; and

FIG. 23 is a graph illustrating the white efficiency of a display device with respect to the taper angle of a dam structure.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein.

It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments will be described with reference to the attached drawings.

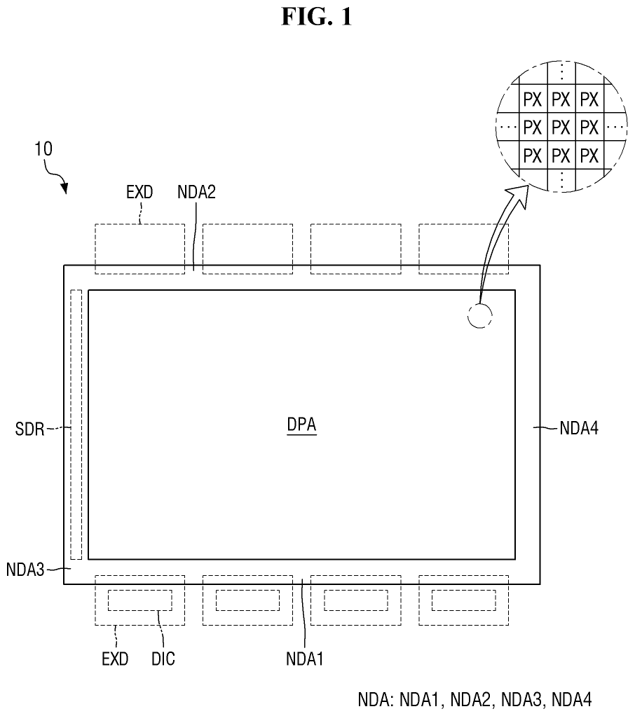

FIG. 1 is a plan view of a display device 10 according to an embodiment.

Referring to FIG. 1, the display device 10 according to the embodiment may be applied to smartphones, mobile phones, tablet personal computers (PCs), personal digital assistants (PDAs), portable multimedia players (PMPs), televisions, game consoles, wristwatch-type electronic devices, head mounted displays, monitors of PCs, laptop computers, car navigation systems, car dashboards, digital cameras, camcorders, outdoor billboards, electronic display boards, medical devices, examination devices, various home appliances such as refrigerators and washing machines, or Internet of things (IoT) devices. In the specification, a television will be described as an example of the display device 10, and the television may have high resolution or ultra-high resolution such as HD, UHD, 4K, or 8K.

The display device 10 according to the embodiment may be variously classified according to a display method. For example, the display device may be classified as an organic light emitting display device, an inorganic electroluminescent (EL) display device, a quantum dot light emitting display device (QED), a micro-light emitting diode display device, a nano-light emitting diode display device, a plasma display panel (PDP), a field emission display (FED) device, a cathode ray tube (CRT) display device, a liquid crystal display (LCD) device, or an electrophoretic display (EPD) device. An organic light emitting display device and an inorganic EL display device will be described below as examples of the display device 10. Unless a special distinction is required, the display devices applied to embodiments will be simply shortened to display devices. However, the embodiments are not limited to the organic light emitting display device or the inorganic EL display device, and other display devices listed above or known in the art can also be applied within the scope sharing the technical spirit.

The display device 10 according to the embodiment may have a quadrilateral shape, for example, a rectangular shape in a plan view. In case that the display device 10 is a television, its long sides may be located in a horizontal direction. However, the disclosure may not be limited thereto, and the long sides may also be located in a vertical direction, or the display device 10 may be rotatably installed so that the long sides can be variably located in the horizontal or vertical direction.

The display device 10 may include a display area DPA and a non-display area NDA. The display area DPA may be an active area in which an image may be displayed. The display area DPA may have a rectangular shape similar to the overall shape of the display device 10 in a plan view, but the disclosure may not be limited thereto.

The display area DPA may include multiple pixels PX. The pixels PX may be arranged in a matrix direction. Each of the pixels PX may be rectangular or square in a plan view. However, the disclosure may nm be limited thereto, and each of the pixels PX may also have a rhombus shape having each side inclined with respect to a side of the display device 10. The pixels PX may include various color pixels PX. For example, the pixels PX may include, but may not be limited to, first-color (red) pixels PX, second-color (green) pixels PX, and third-color (blue) pixels PX. These color pixels PX may be alternately arranged in a stripe or PernTile™ type.

The non-display area NDA may be disposed around the display area DPA. The non-display area NDA may entirely or partially surround the display area DPA, The display area DPA may be rectangular, and the non-display area NDA may be adjacent to four sides of the display area DPA. The non-display area NDA may form a bezel of the display device 10.

Driving circuits or driving elements for driving the display area DPA may be disposed in the non-display area NDA. In an embodiment, a pad part may be provided on a display substrate of the display device 10 in a first non-display area NDA1 disposed adjacent to a first long side (a lower side in FIG. 1) of the display device 10 and a second non-display area NDA2 disposed adjacent to a second long side (an upper side in FIG. 1), and external devices EXD may be mounted on pad electrodes of the pad part. Examples of the external devices EXD may include connection films, printed circuit boards, driving chips DIC, connectors, and wiring connection films. A scan driver SDR formed on (e.g., formed directly on) the display substrate of the display device 10 may be disposed in a third non-display area NDA3 disposed adjacent to a first short side (a left side in FIG. 1) of the display device 10. However, the disclosure may not be limited thereto, and the scan driver SDR may also be disposed on a second short side (a right side in FIG. 1) of the display device 10. A fourth non-display area NDA4 opposite from the third non-display area NDA3 may or may not include a driving circuit or driving element.

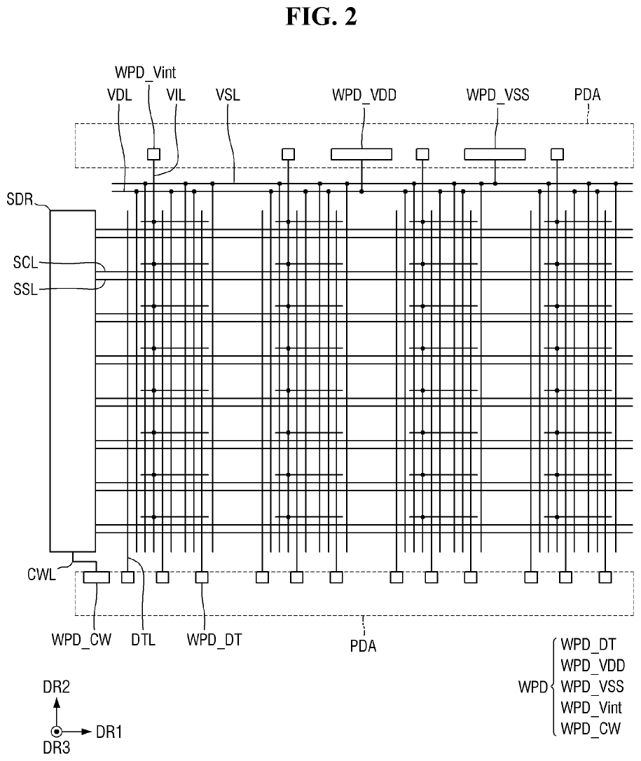

FIG. 2 is a schematic layout view illustrating lines included in the display device 10 according to the embodiment.

Referring to FIG. 2, the display device 10 may include multiple lines. The lines may include scan lines SCL, sensing lines SSL, data lines DTL, initialization voltage lines VIL, a first voltage line VDL, and a second voltage line VSL. Although not illustrated in the drawing, other lines may be further disposed in the display device 10.

The scan lines SCL and the sensing signal lines SSL may extend in a first direction DR1. The scan lines SCL and the sensing signal lines SSL may be electrically connected to the scan driver SDR. The scan driver SDR may include a driving circuit. The scan driver SDR may be disposed on a side of the display area DPA in the first direction DR1, but the disclosure may not be limited thereto. The scan driver SDR may be electrically connected to a signal connection line CWL, and at least one end of the signal connection line CWL may form a pad WPD_CW in a pad area PDA of the non-display area NDA and thus may be electrically connected to an external device.

As used herein, the term “connect” may mean that any one member and another member may be extended to each other not only through physical contact but also through another member. It can be understood that any one part and another part may be extended to each other as being integral with each other. Further, the connection between any one member and another member can be interpreted to include electrical connection through another member in addition to connection through direct contact.

The data lines DTL and the initialization voltage lines VIL may extend in a second direction DR2 intersecting the first direction DR1. Each of the initialization voltage lines VIL may include a portion extending in the second direction DR2 and may further include portions branching from the above portion in the first direction DR1. Each of the first voltage line VDL and the second voltage line VSL may also include portions extending in the second direction DR2 and a portion electrically connected to the above portions and extending in the first direction DR1. The first voltage line VDL and the second voltage line VSL may have a mesh structure, but the disclosure may not be limited thereto. Although not illustrated in the drawing, each pixel PX of the display device 10 may be electrically connected to at least one data line DTL, an initialization voltage line VIL, the first voltage line VDL, and the second voltage line VSL.

The data lines DTL, the initialization voltage lines VIL, the first voltage line VDL, and the second voltage line VSL may be electrically connected to one or more wiring pads WPD. Each wiring pad WPD may be disposed in a pad area PDA. In an embodiment, wiring pads WPD_DT (hereinafter, referred to as ‘data pads’) of the data lines DTL may be disposed in a pad area PDA on a side of the display area DPA in the second direction DR2, and wiring pads WPD_Vint (hereinafter, referred to as ‘initialization voltage pads’) of the initialization voltage lines VIL, a wiring pad WPD_VDD (hereinafter, referred to as a ‘first power pad’) of the first voltage line VDL, and a wiring pad WPD_VSS (hereinafter, referred to as a ‘second power pad’) of the second voltage line VSL may be disposed in a pad area PDA located on another side of the display area DPA in the second direction DR2. For another example, the data pads WPD_DT, the initialization voltage pads WPD_Vint, the first power pad WPD_VDD, and the second power pad WPD_VSS may all be disposed in the same area, for example, in the non-display area NDA located on an upper side of the display area DPA. The external devices EXD may be mounted on the wiring pads WPD. The external devices EXD may be mounted on the wiring pads WPD through anisotropic conductive films, ultrasonic bonding, or the like.

Each pixel PX or subpixel SPX of the display device 10 includes a pixel driving circuit. The above-described lines may transmit driving signals to each pixel driving circuit while passing through or around each pixel PX. The pixel driving circuit may include a transistor and a capacitor. The number of transistors and capacitors in each pixel driving circuit can be variously changed. According to an embodiment, the pixel driving circuit of each subpixel SPXn of the display device 10 may have a 3T1C structure including three transistors and one capacitor. Although the pixel driving circuit may be described below using the 3T1C structure as an example, the disclosure may not be limited thereto, and other various modified pixel structures such as a 2T1C structure, a 7T1C structure, and a 6T1C structure may be also applicable.

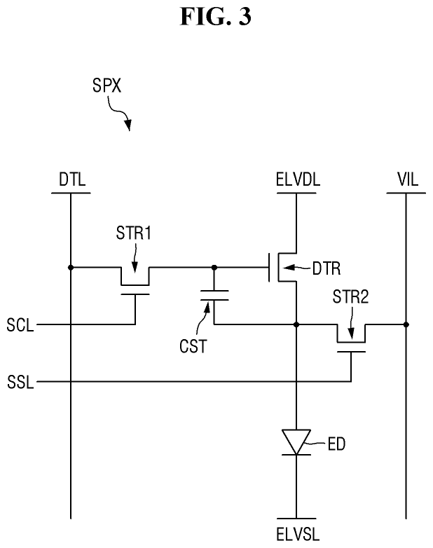

FIG. 3 is a schematic diagram of an equivalent circuit of a subpixel SPX according to an embodiment.

Referring to FIG. 3, each subpixel SPX of the display device 10 according to the embodiment includes three transistors DTR, STR1 and STR2 and one storage capacitor CST in addition to a light emitting element ED.

The light emitting element ED emits light according to a current supplied through a driving transistor DTR. The light emitting element ED may be implemented as an inorganic light emitting diode, an organic light emitting diode, a micro-light emitting diode, or a nano-light emitting diode.

A first electrode (i.e., an anode) of the light emitting element ED may be connected to a source electrode of the driving transistor DTR, and a second electrode (i.e., a cathode) may be electrically connected to a second power line ELVSL to which a low potential voltage (a second power supply voltage) lower than a high potential voltage (a first power supply voltage) of a first power line ELVDL may be supplied.

The driving transistor DTR adjusts a current flowing from the first power line ELVDL, to which the first power supply voltage may be supplied, to the light emitting element ED according to a voltage difference between a gate electrode and the source electrode. The driving transistor DTR may have the gate electrode electrically connected to a first electrode of a first transistor STR1, the source electrode electrically connected to the first electrode of the light emitting element ED, and a drain electrode electrically connected to the first power line ELVDL to which the first power supply voltage may be applied.

The first transistor STR1 may be turned on by a scan signal of a scan line SCL to connect a data line DTL to the gate electrode of the driving transistor DTR. The first transistor STR1 may have a gate electrode electrically connected to the scan line SCL, the first electrode electrically connected to the gate electrode of the driving transistor DTR, and a second electrode electrically connected to the data line DTL.

A second transistor STR2 may be turned on by a sensing signal of a sensing signal line SSL to connect an initialization voltage line VIL to the source electrode of the driving transistor DTR. The second transistor STR2 may have a gate electrode electrically connected to the sensing signal line SSL, a first electrode electrically connected to the initialization voltage line VIL, and a second electrode electrically connected to the source electrode of the driving transistor DTR.

In an embodiment, the first electrode of each of the first and second transistors STR1 and STR2 may be a source electrode, and the second electrode may be a drain electrode. However, the disclosure may not be limited thereto, and the opposite may also be the case.

The capacitor CST may be formed between the gate electrode and the source electrode of the driving transistor DTR. The storage capacitor CST stores a difference between a gate voltage and a source voltage of the driving transistor DTR.

The driving transistor DTR and the first and second transistors STR1 and STR2 may be formed as thin-film transistors. Although a case where the driving transistor DTR and the first and second switching transistors STR1 and STR2 may be N-type metal oxide semiconductor field effect transistors (MOSFETs) has been described in FIG. 3, the disclosure may not be limited thereto. The driving transistor DTR and the first and second switching transistors STR1 and STR2 may also be formed as P-type MOSFETs, or some of them may be formed as N-type MOSFETs, and another may be formed as a P-type MOSFET.

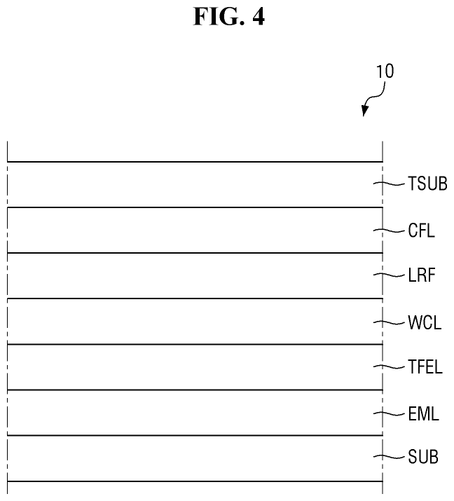

FIG. 4 is a schematic cross-sectional view of the display device 10 according to the embodiment.

Referring to FIG. 4, the display device 10 according to the embodiment may include a substrate SUB, a light emitting element layer EML, a thin-film encapsulation layer TFEL, a wavelength conversion layer WCL, a filling layer LRF, a color filter layer CFL, and a counter substrate TSUB.

The substrate SUB may be an insulating substrate. The substrate SUB may include a transparent material. For example, the substrate SUB may include a transparent insulating material such as glass or quartz. The substrate SUB may be a rigid substrate. However, the disclosure may not be limited thereto, and the substrate SUB may also include plastic such as polyimide or may have flexible characteristics so that it can be curved, bent, folded, or rolled.

The light emitting element layer EML may be disposed on the substrate SUB. The light emitting element layer EML may include multiple switching elements and multiple light emitting elements ED disposed in each subpixel. The switching elements may drive the light emitting elements ED so that the light emitting elements ED can emit light.

The thin-film encapsulation layer TFEL may be disposed on the light emitting element layer EML. The thin-film encapsulation layer TFEL may include an organic layer disposed between multiple inorganic layers to protect the light emitting element layer EML from external moisture and oxygen.

The wavelength conversion layer WCL may be disposed on the thin-film encapsulation layer TFEL. The wavelength conversion layer WCL may convert the wavelength of light emitted from the light emitting element layer EML to output red light, green light, and blue light.

The filling layer LRF may be disposed on the wavelength conversion layer WCL. The filling layer LRF may improve light efficiency by totally reflecting light emitted from the wavelength conversion layer WCL at an interface with the wavelength conversion layer WCL. The filling layer LRF may include a low-refractive material according to embodiments to be described later.

The color filter layer CFL may be disposed on the filling layer LRF. The color filter layer CFL may filter light incident from the outside to reduce reflection of the external light and may improve the color characteristics of light emitted through the wavelength conversion layer WCL.

The counter substrate TSUB may be disposed on the color filter layer CFL. The counter substrate TSUB may encapsulate the light emitting element layer EML together with the substrate SUB. The counter substrate TSUB may include a transparent material. For example, the counter substrate TSUB may include a transparent insulating material such as glass or quartz.

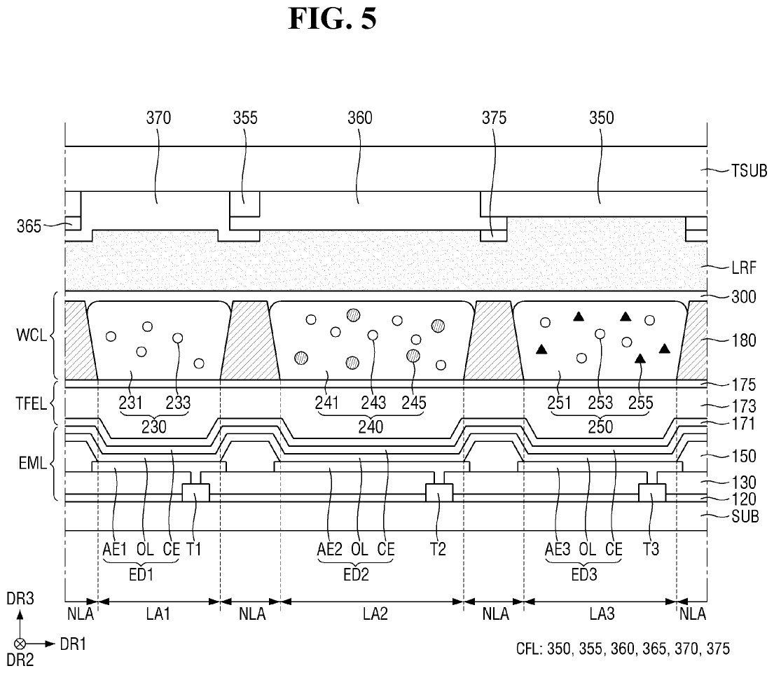

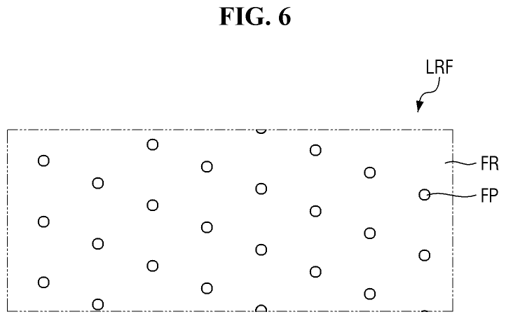

FIG. 5 is a schematic cross-sectional view of the display device 10 according to the embodiment. FIG. 6 is a schematic cross-sectional view of the filling layer LRF of the display device 10 according to the embodiment.

Referring to FIGS. 5 and 6, the display device 10 according to the embodiment may include the substrate SUB, the light emitting element layer EML, the thin-film encapsulation layer TFEL, the wavelength conversion layer WCL, the filling layer LRF, the color filter layer CFL, and the counter substrate TSUB.

Multiple light emitting areas LA1 through LA3 and a non-light emitting area NLA may be defined in the substrate SUB. The light emitting areas LA1 through LA3 may be areas where light generated by light emitting elements ED1 through ED3 may be emitted to the outside, and the non-light emitting area NLA may be an area where light may not be emitted to the outside. In an embodiment, a first light emitting area LA1, a second light emitting area LA2, and a third light emitting area LA3 may be sequentially and repeatedly arranged in the first direction DR1 in the display area DPA.

The first light emitting area LA1, the second light emitting area LA2, and the third light emitting area LA3 may have different widths measured in the first direction DR1. For example, the width of the first light emitting area LA1 may be smaller than the width of the third light emitting area LA3, and the width of the third light emitting area LA3 may be smaller than the width of the second light emitting area LA2. However, the disclosure may not be limited thereto, and the first light emitting area LA1, the second light emitting area LA2 and the third light emitting area LA3 may also have the same width measured in the first direction DR1.

The light emitting areas LA1 through LA3 may emit light of different colors. In an embodiment, the first light emitting area LA1 may emit light of a first color, the second light emitting area LA2 may emit light of a second color, and the third light emitting area LA3 may emit light of a third color. In an embodiment, the light of the first color may be blue light having a peak wavelength in the range of about 440 to about 480 nm, and the light of the second color may be red light having a peak wavelength in the range of about 610 to about 650 nm. The light of the third color may be green light having a peak wavelength in the range of about 510 to about 550 nm. However, the disclosure may not be limited thereto, and the light of the second color may also be green light, and the light of the third color may also be red light.

Switching elements T1 through T3 may be disposed on the substrate SUB. In an embodiment, a first switching element T1 may be located on the substrate SUB in the first light emitting area LA1, a second switching element T2 may be located in the second light emitting area LA2, and a third switching element T3 may be located in the third light emitting area LA3. However, the disclosure may not be limited thereto. In an embodiment, at least any one of the first switching element T1, the second switching element T2, and the third switching element T3 may be located in the non-light emitting area NLA.

In an embodiment, each of the first switching element T1, the second switching element T2, and the third switching element T3 may be a thin-film transistor including amorphous silicon, polysilicon, or an oxide semiconductor. Although not illustrated in the drawings, multiple signal lines (e.g., gate lines, data lines, power lines, etc.) which transmit signals to each switching element may be further disposed on the substrate SUB. Each of the switching elements T1 through T3 may include a first insulating layer 120. For example, the first insulating layer 120 may be a gate insulating film or an interlayer insulating film of a thin-film transistor. The gate insulating film or the interlayer insulating film may be a single layer or a multilayer including any one or more of silicon oxide (SiOₓ), silicon nitride oxide (SiOₓN_{y}), and silicon nitride (SiNₓ).

A second insulating layer 130 may be located on the first switching element T1, the second switching element T2, and the third switching element T3. In an embodiment, the second insulating layer 130 may be a planarization layer. In an embodiment, the second insulating layer 130 may be made of an organic layer. For example, the second insulating layer 130 may include acrylic resin, epoxy resin, imide resin, ester resin, or a combination thereof. In an embodiment, the second insulating layer 130 may include a positive photosensitive material or a negative photosensitive material.

A first anode AE1, a second anode AE2, and a third anode AE3 may be located on the second insulating layer 130. The first anode AE1 may be located in the first light emitting area LA1, but at least a portion of the first anode AE1 may extend to the non-light emitting area NLA. The second anode AE2 may be located in the second light emitting area LA2, but at least a portion of the second anode AE2 may extend to the non-light emitting area NLA. The third anode AE3 may be located in the third emitting area LA3, but at least a portion of the third anode AE3 may extend to the non-light emitting area NLA. The first anode AE1 may penetrate the second insulating layer 130 and may be electrically connected to the first switching element T1. The second anode AE2 may penetrate the second insulating layer 130 and may be electrically connected to the second switching element T2. The third anode AE3 may penetrate the second insulating layer 130 and may be electrically connected to the third switching element T3.

In an embodiment, widths or areas of the first anode AE1, the second anode AE2, and the third anode AE3 may be different from each other. For example, the width of the first anode AE1 may be smaller than the width of the second anode AE2, and the width of the third anode AE3 may be smaller than the width of the second anode AE2 and greater than the width of the first anode AE1. The area of the first anode AE1 may be smaller than the area of the second anode AE2, and the area of the third anode AE3 may be smaller than the area of the second anode AE2 and larger than the area of the first anode AE1. The area of the first anode AE1 may be smaller than the area of the second anode AE2, and the area of the third anode AE3 may be larger than the area of the second anode AE2 and the area of the first anode AE1. However, the disclosure may not be limited to the above-described embodiment. In an embodiment, the widths or areas of the first anode AE1, the second anode AE2, and the third anode AE3 may be substantially the same.

The first anode AE1, the second anode AE2, and the third anode AE3 may be reflective electrodes. The first anode AE1, the second anode AE2, and the third anode AE3 may have a stacked structure of a material layer having a high work function such as indium tin oxide (ITO), indium zinc oxide (IZO), zinc oxide (ZnO), indium tin zinc oxide (ITZO) indium oxide (In₂O₃), or a mixture thereof and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or a mixture thereof. The material layer having a high work function may be disposed on the reflective material layer so that it may be located close to a light emitting layer OL. The first anode AE1, the second anode AE2, and the third anode AE3 may have, but may not be limited to, a multilayer structure of ITO/Mg, ITO/MgF, ITO/Ag, or ITO/Ag/ITO.

A pixel defining layer 150 may be located on the first anode AE1, the second anode AE2, and the third anode AE3. The pixel defining layer 150 may include an opening exposing the first anode AE1, an opening exposing the second anode AE2 and an opening exposing the third anode AE3 and may define the first light emitting area LA1, the second light emitting area LA2, the third light emitting area LA3 and the non-light emitting area NLA. An area of the first anode AE1 which may be exposed without being covered by the pixel defining layer 150 may be the first light emitting area LA1. An area of the second anode AE2 which may be exposed without being covered by the pixel defining layer 150 may be the second light emitting area LA2. An area of the third anode AE3 which may be exposed without being covered by the pixel defining layer 150 may be the third light emitting area LA3. An area where the pixel defining layer 150 may be located may be the non-light emitting area NLA.

The pixel defining layer 150 may include an organic insulating material such as polyacrylate resin, epoxy resin, phenolic resin, polyamide resin, polyimide resin, unsaturated polyester resin, polyphenylene resin, polyphenylene sulfide resin, benzocyclobutene (BCB), or a combination thereof.

In an embodiment, the pixel defining layer 150 may overlap a bank 180 of the wavelength conversion layer WCL which will be described later. The light emitting layer OL may be disposed on the first anode AE1, the second anode AE2, and the third anode AE3. In an embodiment in which the display device 10 may be an organic light emitting display device, the light emitting layer OL may include an organic layer including an organic material. The organic layer includes an organic light emitting layer, and in some cases, may further include at least one of a hole injection layer, a hole transport layer, an electron transport layer, and an electron injection layer as an auxiliary layer that assists light emission.

In an embodiment, the light emitting layer OL may have a tandem structure including multiple organic light emitting layers overlapping each other in a thickness direction and a charge generation layer disposed between them. The organic light emitting layers overlapping each other may emit light of the same wavelength or may emit light of different wavelengths. For example, the organic light emitting layers overlapping each other may include an organic light emitting layer that emits light of a green wavelength and an organic light emitting layer that emits light of a blue wavelength. In an embodiment, the organic light emitting layers overlapping each other may include an organic light emitting layer that emits light of a red wavelength, an organic light emitting layer that emits light of a green wavelength, and an organic light emitting layer that emits light of a blue wavelength.

In an embodiment, the light emitting layer OL may be in the shape of a continuous layer formed over the light emitting areas LA1 through LA3 and the non-light emitting area NLA. The wavelength of light emitted from the light emitting layer OL may be the same. For example, the light emitting layer OL may emit blue light, light of a white wavelength, or ultraviolet light in the light emitting areas LA1 through LA3.

A cathode CE may be located on the light emitting layer OL. In an embodiment, the cathode CE may have translucency or transparency. In case that the cathode CE has translucency, it may include Ag, Mg, Cu, Al, Pt, Pd, Au, Ni, Nd, Ir, Cr, Li, Ca, LiF/Ca, LiF/Al, Mo, Ti, or a compound or mixture thereof (e.g., a mixture of Ag and Mg). In case that a thickness of the cathode CE is tens to hundreds of angstroms, the cathode CE may have translucency.

In case that the cathode CE has transparency, it may include a transparent conductive oxide (TCO). For example, the cathode CE may include tungsten oxide (WₓOₓ), titanium oxide (TiO₂), indium tin oxide (ITO), indium zinc oxide (IZO), zinc oxide (ZnO), indium tin zinc oxide (ITZO), magnesium oxide (MgO), or a combination thereof.

The first anode AEL, the light emitting layer OL, and the cathode CE may form a first light emitting element ED1. The second anode AE2, the light emitting layer OL, and the cathode CE may form a second light emitting element ED2. The third anode AE3, the light emitting layer OL, and the cathode CE may form a third light emitting element ED3. Each of the first light emitting element ED1, the second light emitting element ED2, and the third light emitting element ED3 may emit source light, and the source light may be provided to the wavelength conversion layer WCL. The source light may be, for example, blue light. However, the disclosure may not be limited thereto, and the source light may also be white light or ultraviolet light. The first light emitting element ED1, the second light emitting element ED2, and the third light emitting element ED3 may be organic light emitting diodes.

The thin-film encapsulation layer TFEL may be located on the cathode CE. The thin-film encapsulation layer TFEL may be commonly located in the first light emitting area LA1, the second light emitting area LA2, the third light emitting area LA3, and the non-light emitting area NLA. In an embodiment, the thin-film encapsulation layer TFEL may cover (e.g., directly cover) the cathode CE.

In an embodiment, the thin-film encapsulation layer TFEL may include a first encapsulating inorganic layer 171, an encapsulating organic layer 173, and a second encapsulating inorganic layer 175 sequentially stacked on each other on the cathode CE.

The first encapsulating inorganic layer 171 and the second encapsulating inorganic layer 175 may each include any one or more of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and lithium fluoride. The encapsulating organic layer 173 may include acrylic resin, methacrylate resin, polyisoprene, vinyl resin, epoxy resin, urethane resin, cellulose resin, perylene resin, or a combination thereof.

However, the structure of the thin-film encapsulation layer TFEL may not be limited to the above example, and the stacked structure of the thin-film encapsulation layer TFEL can be variously changed.

The wavelength conversion layer WCL may be disposed on the light emitting element layer EML including the thin-film encapsulation layer TFEL.

The wavelength conversion layer WCL may include the bank 180, a light transmission pattern 230, a first wavelength conversion pattern 240, a second wavelength conversion pattern 250, and a capping layer 300.

The bank 180 may be disposed on the thin-film encapsulation layer TFEL. The bank 180 may define the light emitting areas LA1 through LA3 and the non-light emitting area NLA. The bank 180 may overlap the non-light emitting area NLA to block transmission of light. More specifically, the bank 180 may be located between the light transmission pattern 230 and the first wavelength conversion pattern 240, between the first wavelength conversion pattern 240 and the second wavelength conversion pattern 250, and between the second wavelength conversion pattern 250 and the light transmission pattern 230 to prevent color mixing between neighboring light emitting areas.

The bank 180 may include an organic light blocking material and may be formed through a process of coating and exposing the organic light blocking material or an inkjet method. For example, the bank 180 may include an organic material and a light blocking dye or pigment mixed with the organic material. Examples of the organic material may include acrylic resin, methacrylate resin, polyisoprene, vinyl resin, epoxy resin, urethane resin, cellulose resin, perylene resin, or a combination thereof. Examples of the dye or pigment may include carbon black.

The light transmission pattern 230 may be disposed on the thin-film encapsulation layer TFEL. The light transmission pattern 230 may overlap the first light emitting area LA1. The light transmission pattern 230 may transmit incident light. In case that source light provided from the first light emitting element ED1 is blue light, the blue source light may pass through the light transmission pattern 230.

In an embodiment, the light transmission pattern 230 may include a first base resin 231 and may further include first scatterers 233 dispersed in the first base resin 231.

The first base resin 231 may be made of a material having relatively high light transmittance. In an embodiment, the first base resin 231 may be made of an organic material. For example, the first base resin 231 may include an organic material such as epoxy resin, acrylic resin, cardo resin, imide resin, or a combination thereof.

The first scatterers 233 may have a refractive index different from that of the first base resin 231 and may form an optical interface with the first base resin 231. For example, the first scatterers 233 may be light scattering particles. The first scatterers 233 may not be particularly limited as long as they may be materials that can scatter at least a portion of transmitted light. However, the first scatterers 233 may be, for example, metal oxide particles or organic particles. The metal oxide may be, for example, titanium oxide (TiO₂), zirconium oxide (ZrO₂), aluminum oxide (Al₂O₃), indium oxide (In₂O₃), zinc oxide (ZnO) tin oxide (SnO₂), or a combination thereof, and the organic particles may be made of, for example, acrylic resin or urethane resin. The first scatterers 233 may scatter incident light in random directions regardless of the incident direction of the incident light without substantially converting the wavelength of the incident light passing through the light transmission pattern 230.

In an embodiment, the light transmission pattern 230 may be formed by applying a photosensitive material and exposing and developing the photosensitive material. However, the disclosure may not be limited thereto, and the light transmission pattern 230, the first wavelength conversion pattern 240 and the second wavelength conversion pattern 250 may also be formed using an inkjet method.

The first wavelength conversion pattern 240 and the second wavelength conversion pattern 250 may be disposed on the thin-film encapsulation layer TFEL.

The first wavelength conversion pattern 240 may be located on the thin-film encapsulation layer TFEL and may overlap the second light emitting area LA2. The first wavelength conversion pattern 240 may convert or shift the peak wavelength of incident light into another specific peak wavelength and output light of the specific peak wavelength. In an embodiment, the first wavelength conversion pattern 240 may convert source light provided from the second light emitting element ED2 into red light having a peak wavelength in the range of about 610 to about 650 nm and may output the red light.

The first wavelength conversion pattern 240 may include a second base resin 241 and first wavelength shifters 245 dispersed in the second base resin 241 and may further include second scatterers 243 dispersed in the second base resin 241.

The second base resin 241 may be made of a material having high light transmittance. In an embodiment, the second base resin 241 may be made of an organic material. The second base resin 241 and the first base resin 231 may be made of a same material or the second base resin 241 may include at least one of the example materials of the first base resin 231.

The first wavelength shifters 245 may convert or shift the peak wavelength of incident light into another specific peak wavelength. In an embodiment, the first wavelength shifters 245 may convert source light (e.g., light of the first color which may be blue light) provided from the second light emitting element ED2 into red light having a single peak wavelength in the range of about 610 to about 650 nm and may output the red light.

The first wavelength shifters 245 may be, for example, quantum dots, quantum rods, or phosphors. For example, the quantum dots may be particulate materials that emit light of a specific color in case that electrons transition from a conduction band to a valence band.

The quantum dots may be semiconductor nanocrystalline materials. The quantum dots may have a specific band gap according to their composition and size. Thus, the quantum dots may absorb light and then emit light having a unique wavelength. Examples of semiconductor nanocrystals of the quantum dots may include group V nanocrystals, group II-VI compound nanocrystals, group III-V compound nanocrystals, group IV-VI nanocrystals, and combinations thereof.

Group II-VI compounds may be selected from binary compounds selected from CdSe, CdTe, ZnS, ZnSe, ZnTe, ZnO, HgS, HgSe, HgTe, MgSe, MgS and mixtures thereof; ternary compounds selected from InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof; and quaternary compounds selected from HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof.

Group III-V compounds may be selected from binary compounds selected from GaN, GaP, GaAs, GaSb, AlN, AlP, AlAs, AlSb, InN, InP, InAs, InSb and mixtures thereof, ternary compounds selected from GaNP, GaNAs, GaNSb, GaPAs, GaPSb, AlNP, AlNAs, AlNSb, AlPAs, AlPSb, InGaP, InNP, InAIP, InNAs, InNSb, InPAs, InPSb, GaAlNP and mixtures thereof; and quaternary compounds selected from GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and mixtures thereof.

Group IV-VI compounds may be selected from binary compounds selected from SnS, SnSe, SnTe, PbS, PbSe, PbTe and mixtures thereof, ternary compounds selected from SnSeS, SnSeTe, SnSTe, PbSeS, PbSeTe, PbSTe, SnPbS, SnPbSe, SnPbTe and mixtures thereof, and quaternary compounds selected from SnPbSSe, SnPbSeTe, SnPbSTe and mixtures thereof. Group IV elements may be selected from silicon (Si), germanium (Ge), and a mixture thereof. Group IV compounds may be binary compounds selected from silicon carbide (SiC), silicon germanium (SiGe), and a mixture thereof.

Here, the binary, ternary or quaternary compounds may be in particles at a uniform concentration or may be in the same particles at partially different concentrations. They may have a core/shell structure in which a quantum dot surrounds another quantum dot. An interface between the core and the shell may have a concentration gradient in which the concentration of an element in the shell may be reduced toward the center.

In an embodiment, the quantum dots may have a core-shell structure including a core containing the above-described nanocrystal and a shell surrounding the core. The shell of each quantum dot may serve as a protective layer for maintaining semiconductor characteristics by preventing chemical denaturation of the core and/or as a charging layer for giving electrophoretic characteristics to the quantum dot. The shell may be a single layer or a multilayer. The shell of each quantum dot may be, for example, a metal or non-metal oxide, a semiconductor compound, or a combination thereof.

For example, the metal or non-metal oxide may be, but may not be limited to, a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ or NiO or a ternary compound such as MgAl₂O₄, CoFe₂O₄, NiFe₂O₄ or CoMn₂O₄.

The semiconductor compound may be, but may not be limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb.

Light emitted from the first wavelength shifters 245 may have a full width at half maximum (FWHM) of an emission wavelength spectrum of about 45 nm or less, about 40 nm or less, or about 30 nm or less. Therefore, the color purity and color reproducibility of the display device 10 can be further improved. The light emitted from the first wavelength shifters 245 may be radiated in various directions regardless of the incident direction of incident light. Therefore, the lateral visibility of the second color displayed in the second light emitting area LA2 can be improved.

A portion of the source light provided from the second light emitting element ED2 may not be converted into red light by the first wavelength shifters 245. However, the portion of the source light which may not be converted into red light may be blocked by the color filter layer CFL disposed above the wavelength conversion layer WCL. On the other hand, red light into which the source light has been converted by the first wavelength conversion pattern 240 may be transmitted through the color filter layer CFL and then emitted to the outside.

The second scatterers 243 may have a refractive index different from that of the second base resin 241 and may form an optical interface with the second base resin 241. For example, the second scatterers 243 may be light scattering particles. Other details of the second scatterers 243 may be substantially the same as or similar to those of the first scatterers 233 described above, and thus a detailed description thereof will be omitted.

The second wavelength conversion pattern 250 may be located on the thin-film encapsulation layer TFEL and may overlap the third light emitting area LA3. The second wavelength conversion pattern 250 may convert or shift the peak wavelength of incident light into another specific peak wavelength and output light of the specific peak wavelength. In an embodiment, the second wavelength conversion pattern 250 may convert source light provided from the third light emitting element ED3 into green light in the range of about 510 to about 550 nm and may output the green light.

The second wavelength conversion pattern 250 may include a third base resin 251 and second wavelength shifters 255 dispersed in the third base resin 251 and may further include third scatterers 253 dispersed in the third base resin 251.

The third base resin 251 may be made of a material having high light transmittance. In an embodiment, the third base resin 251 may be made of an organic material. The third base resin 251 and the first base resin 231 may be made of a same material or the third base resin 251 may include at least one of the example materials of the first base resin 231.

The second wavelength shifters 255 may convert or shift the peak wavelength of incident light to another specific peak wavelength. In an embodiment, the second wavelength shifters 255 may convert source light (e.g., blue light) having a peak wavelength in the range of about 440 to about 480 nm into green light having a peak wavelength in the range of about 510 to about 550 nm.

The second wavelength shifters 255 may be, for example, quantum dots, quantum rods, or phosphors. A more detailed description of the second wavelength shifters 255 may be substantially the same as or similar to the above description of the first wavelength shifters 245 and thus will be omitted. In an embodiment, both the first wavelength shifters 245 and the second wavelength shifters 255 may be composed of quantum dots. The particle size of quantum dots that form the first wavelength shifters 245 may be larger than the particle size of quantum dots that form the second wavelength shifters 255.

The third scatterers 253 may have a refractive index different from that of the third base resin 251 and may form an optical interface with the third base resin 251. For example, the third scatterers 253 may be light scattering particles. Other details of the third scatterers 253 may be substantially the same as or similar to those of the second scatterers 243 described above, and thus a detailed description thereof will be omitted.

Source light emitted from the third light emitting element ED3 may be provided to the second wavelength conversion pattern 250, and the second wavelength shifters 255 may convert the source light emitted from the third light emitting element ED3 into green light having a peak wavelength in the range of about 510 to about 550 nm and may output the green light.

A portion of the source light may be transmitted through the second wavelength conversion pattern 250 without being converted into green light by the second wavelength shifters 255. However, the portion of the source light which may not be converted into green light may be blocked by the color filter layer CFL. On the other hand, green light into which the source light has been converted by the second wavelength conversion pattern 250 may be transmitted through the color filter layer CFL and then emitted to the outside.

The capping layer 300 may be disposed on the bank 180, the light transmission pattern 230, the first wavelength conversion pattern 240, and the second wavelength conversion pattern 250 to cover them. Therefore, the capping layer 300 can prevent damage to or contamination of the bank 180, the light transmission pattern 230, the first wavelength conversion pattern 240 and the second wavelength conversion pattern 250 by preventing penetration of impurities such as moisture or air from the outside.

The capping layer 300 may be made of an inorganic material. For example, the capping layer 300 may include silicon nitride, aluminum nitride, zirconium nitride, titanium nitride, hafnium nitride, tantalum nitride, silicon oxide, aluminum oxide, titanium oxide, tin oxide, silicon oxynitride, or a combination thereof.

The filling layer LRF may be disposed on the capping layer 300. The filling layer LRF may be disposed on (e.g., directly on) the capping layer 300 and between the wavelength conversion layer WCL and the color filter layer CFL. The filling layer LRF may contact each of the wavelength conversion layer WCL and the color filter layer CFL. The filling layer LRF may entirely cover the top of the wavelength conversion layer WCL. The filling layer LRF may be disposed in the entire display area DPA (see FIG. 1) of the display device 10. For example, the filling layer LRF may be disposed on the light emitting areas LA1 through LA3 and the non-light emitting area NLA in the display area DPA. The filling layer LRF may extend to the non-display area NDA (see FIG. 1) of the display device 10.

The filling layer LRF may have a relatively lower refractive index than the light transmission pattern 230, the first wavelength conversion pattern 240, the second wavelength conversion pattern 250, and the capping layer 300. The filling layer LRF may totally reflect some of the light emitted from the wavelength conversion layer WCL due to a difference in refractive index at an interface with the capping layer 300. The totally reflected light may re-enter the first wavelength conversion pattern 240 and the second wavelength conversion pattern 250 and be reused for wavelength conversion or may be re-reflected by the scatterers of the wavelength conversion layer WCL to the front. Therefore, the front light emission efficiency of the display device 10 including the filling layer LRF can be improved.

The filling layer LRF may include a filling resin FR and filling particles FP dispersed in the filling resin FR. The filling resin FR may be made of a material having high light transmittance. For example, the filling resin FR may include silicone, acryl, epoxy, polyacrylate, polyurethane, polyethylene, ester resin, or a combination thereof.

The filling particles FP may be hollow. The filling particles FP may include hollow particles such as silica (SiO₂), magnesium fluoride (MgF₂), iron oxide (Fe₃O₄), or a combination thereof. For example, a hollow particle may include a shell made of one or more of the above materials and be hollow inside the shell. In an embodiment, the hollow particles may have a diameter in a range of about 20 to about 200 nm, but the disclosure may not be limited thereto. The filling layer LRF may be formed by mixing the filling resin FR with the filling particles FP, a dispersant, a thermal initiator, or a photoinitiator.

In an embodiment, the filling layer LRF may include a filling resin FR, and the filling resin FR may include a silicone compound. For example, the filling layer LRF may include a diacrylate-based silicone compound, a polyacrylate-based silicone compound, a polyurethane-based silicone compound, a polyethylene-based silicone compound, or a combination thereof and may be represented by the following chemical formulas.

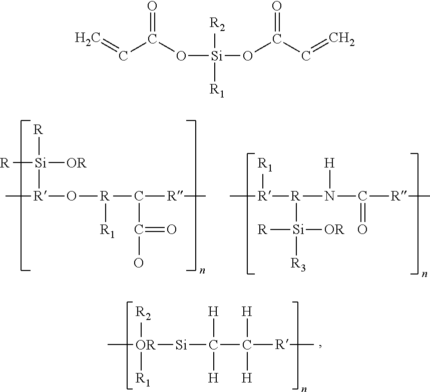

where R, R′, R″, R₁, R₂, and R₃ may each independently be hydrogen or an alkyl group, and n may be in a range of about 1,000 to about 100,000.

A thickness of the filling layer LRF may be in a range of about 0.1 to about 4.5 um. If the thickness of the filling layer LRF may be about 0.1 um or more, the flatness of the filling layer LRF can be secured, and a gap with the color filter layer CFL can be readily formed. If the thickness of the filling layer LRF may be about 4.5 um or less, it may be possible to prevent defects by preventing penetration of moisture or oxygen from the outside through the filling layer LRF.

A refractive index of the filling layer LRF may be in a range of about 1.05 to about 1.4. If the refractive index of the filling layer LRF may be about 1.05 or more, a front side luminance ratio of the display device 10 can be increased. If the refractive index of the filling layer LRF may be about 1.4 or less, a reduction in the front luminance efficiency of the display device 10 can be prevented.

In an embodiment, the filling layer LRF disposed between the wavelength conversion layer WCL and the color filter layer CFL can increase the front side luminance ratio of the display device 10 and prevent a reduction in the front luminance efficiency.

The color filter layer CFL may be disposed on the wavelength conversion layer WCL, and the counter substrate TSUB may be disposed on the color filter layer CFL.

The color filter layer CFL may include a first color filter 350, a second color filter 360, and a third color filter 370. The color filter layer CFL may include a first color pattern 355, a second color pattern 365, and a third color pattern 375.

The first color filter 350 may be disposed between the counter substrate TSUB and the filling layer LRF and may overlap the third light emitting area LA3. The first color filter 350 may overlap the third light emitting element ED3 and the second wavelength conversion pattern 250. The first color pattern 355 may be spaced apart from the first color filter 350 and may overlap the non-light emitting area NLA. The first color filter 350 may contact (e.g., directly contact) the filling layer LRF.

The first color filter 350 and the first color pattern 355 may selectively transmit light of the third color (e.g., green light) and may block or absorb light of the first color (e.g., blue light) and light of the second color (e.g., red light). In an embodiment, the first color filter 350 may be a green color filter and may include a green colorant such as green dye or green pigment. As used herein, the term “colorant” is a concept encompassing both a dye and a pigment.

The second color filter 360 may be disposed between the counter substrate TSUB and the filling layer LRF and may overlap the second light emitting area LA2. The second color filter 360 may overlap the second light emitting element ED2 and the first wavelength conversion pattern 240. In an embodiment, a side of the second color filter 360 may overlap the non-light emitting area NLA and the adjacent first color filter 350. Another side of the second color filter 360 may overlap the non-light emitting area NLA and the first color pattern 355. The second color pattern 365 may be spaced apart from the second color filter 360 and may overlap the non-light emitting area NLA. The second color pattern 365 may overlap the first color filter 350 in the non-light emitting area NLA. The second color filter 360 may contact (e.g., directly contact) the filling layer LRF.

The second color filter 360 and the second color pattern 365 may selectively transmit light of the second color (e.g., red light) and may block or absorb light of the first color (e.g., blue light) and light of the third color (e.g., green light). For example, the second color filter 360 may be a red color filter and may include a red colorant such as red dye or red pigment.

The third color filter 370 may be disposed between the counter substrate TSUB and the filling layer LRF and may overlap the first light emitting area LA1. The third color filter 370 may overlap the first light emitting element ED1 and the light transmission pattern 230. In an embodiment, a side of the third color filter 370 may overlap the non-light emitting area NLA and the adjacent second color filter 360. Another side of the third color filter 370 may overlap the non-light emitting area NLA and may overlap an adjacent first color filter 350 and the second color pattern 365. The third color pattern 375 may be spaced apart from the third color filter 370 and may overlap the non-light emitting area NLA. The third color pattern 375 may overlap the second color filter 360 in the non-light emitting area NLA. The third color filter 370 and the third color pattern 375 may contact (e.g., directly contact) the filling layer LRF.

The third color filter 370 may selectively transmit light of the first color (e.g., blue light) and may block or absorb light of the second color (e.g., red light) and light of the third color (e.g., green light). For example, the third color filter 370 may be a blue color filter and may include a blue colorant such as blue dye or blue pigment.

As described above, the first through third color filters 350, 360 and 370 and the first through third color patterns 355, 365 and 375 may overlap each other in the non-light emitting area NLA to block or absorb light. For example, the first color pattern 355, the second color filter 360 and the third color filter 370 may overlap each other in the non-light emitting area NLA disposed on a side of the second light emitting area LA2, and the first color filter 350, the second color filter 360 and the third color pattern 375 may overlap each other in the non-light emitting area NLA disposed on another side of the second light emitting area LA2.

Since the display device 10 according to the embodiment includes the filling layer LRF disposed between the wavelength conversion layer WCL and the color filter layer CFL as described above, the front side luminance ratio of the display device 10 can be increased, and a reduction in the front luminance efficiency of the display device 10 can be prevented.

A method of manufacturing the display device 10 according to the embodiment illustrated in FIG. 5 will now be described.

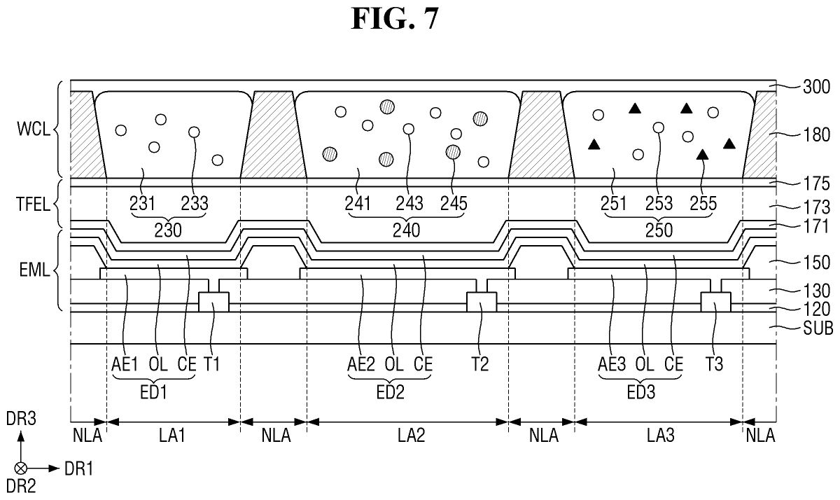

FIGS. 7 through 9 are schematic cross-sectional views illustrating each process in a method of manufacturing a display device according to an embodiment.

Referring to FIG. 7, a light emitting element layer EML may be formed by forming multiple switching elements T1 through T3, multiple light emitting elements ED1 through ED3, first and second insulating layers 120 and 130, and a pixel defining layer 150 on a substrate SUB. A thin-film encapsulation layer TFEL may be formed by forming a first encapsulating inorganic layer 171, an encapsulating organic layer 173, and a second encapsulating inorganic layer 175 on the light emitting element layer EML.

Each of the light emitting element layer EML and the thin-film encapsulation layer TFEL disposed on the substrate SUB may be formed by depositing a material that forms the layer, for example, a metal material and patterning the material using a mask. Each of the first and second insulating layers 120 and 130 and the pixel defining layer 150 may be formed by applying a material that forms the layer, for example, an insulating material or, if desirable, by patterning the material using a mask. The structures of the layers disposed on the substrate SUB may be the same as those described above, and thus a detailed description thereof will be omitted.

A wavelength conversion layer WCL may be formed by patterning a bank 180 on the thin-film encapsulation layer TFEL, forming a light transmission pattern 230, a first wavelength conversion pattern 240 and a second wavelength conversion pattern 250 between portions of the bank 180, and stacking a capping layer 300.

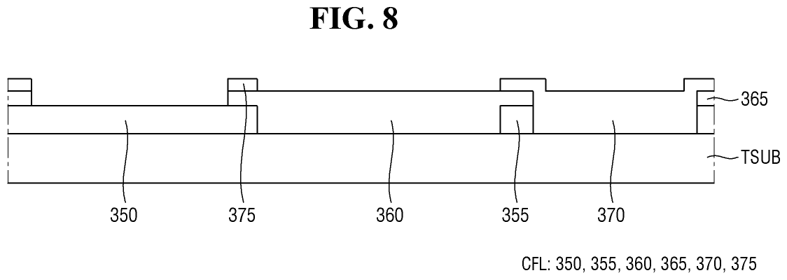

Referring to FIG. 8, a first color filter material may be applied and patterned on a counter substrate TSUB to form a first color filter 350 and a first color pattern 355. A second color filter material may be applied and patterned on the counter substrate TSUB to form a second color filter 360 and a second color pattern 365. A third color filter material may be applied and patterned on the counter substrate TSUB to form a third color filter 370 and a third color pattern 375. As a result, a color filter layer CFL may be formed.

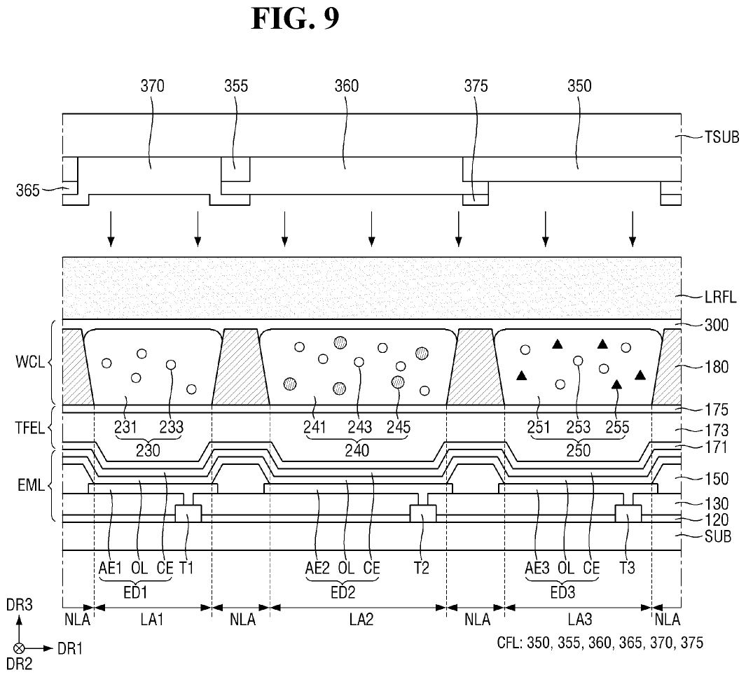

Referring to FIG. 9, a filling material layer LRFL may be formed by applying a filling material on the substrate SUB on which the wavelength conversion layer WCL may be formed. The filling material layer LRFL may be formed using a solution process such as spin coating, slit coating, or inkjet printing. In the current embodiment, the filling material layer LRFL may be formed on the substrate SUB. However, the disclosure may not be limited thereto, and the filling material layer LRFL may also be formed on the counter substrate TSUB.

The counter substrate TSUB may be aligned on the substrate SUB. Here, the counter substrate TSUB may be aligned such that the color filter layer CFL faces the substrate SUB. The counter substrate TSUB and the substrate SUB may be pressed and bonded together. The counter substrate TSUB and the substrate SUB may be bonded together such that the first color filter 350 corresponds to a third light emitting area LA3, the second color filter 360 corresponds to a second light emitting area LA2, and the third color filter 370 corresponds to a first light emitting area LA1.

The filling material layer LRFL may be cured by irradiating ultraviolet light or applying heat depending on the material of the filling material layer LRFL. As a result, a filling layer LRF may be formed. Therefore, the display device 10 having the filling layer LRF disposed between the substrate SUB and the counter substrate TSUB can be manufactured.

Display devices 10 according to other embodiments will now be described with reference to other drawings.

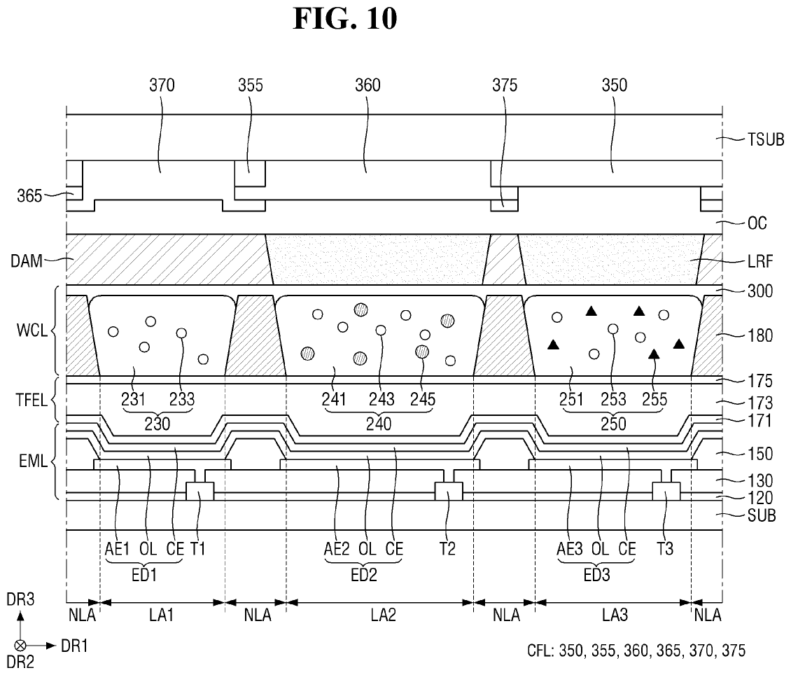

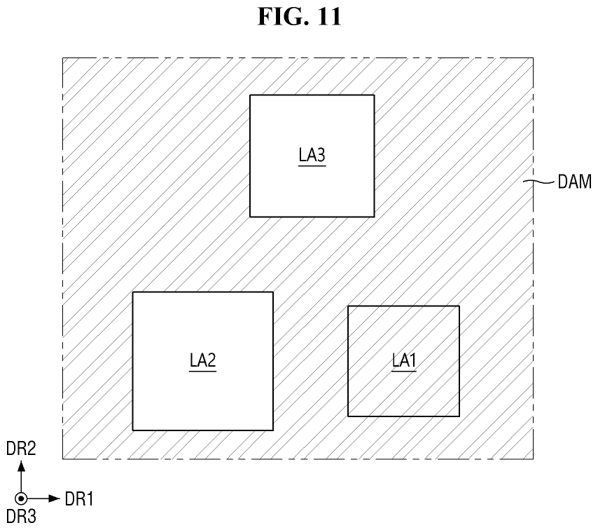

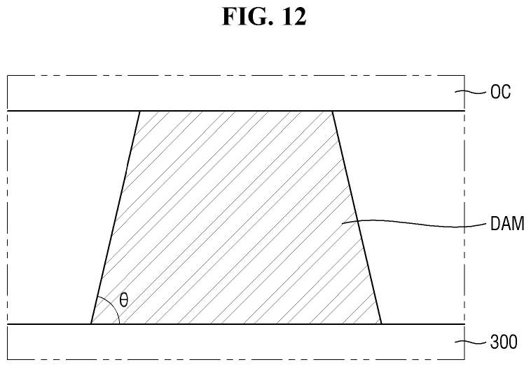

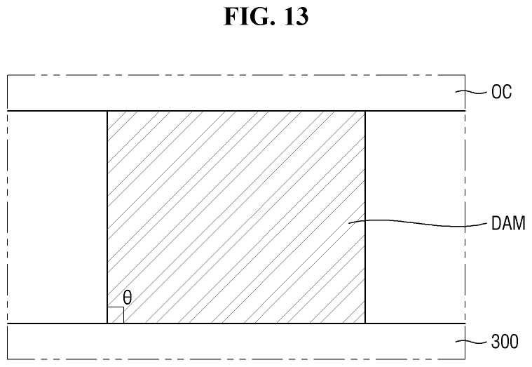

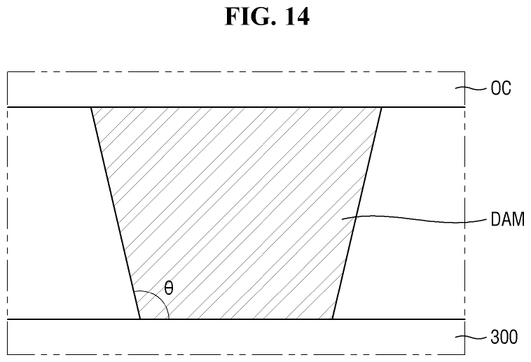

FIG. 10 is a schematic cross-sectional view of a display device 10 according to an embodiment. FIG. 11 is a plan view illustrating each light emitting area of the display device 10 of FIG. 10. FIG. 12 is a schematic cross-sectional view of an example of a dam structure DAM according to an embodiment. FIG. 13 is a schematic cross-sectional view of another example of the dam structure DAM according to the embodiment. FIG. 14 is a schematic cross-sectional view of another example of the dam structure DAM according to the embodiment.

Referring to FIGS. 10 through 14, the current embodiment may be different from the embodiment of FIGS. 5 through 9 described above in that it further includes the dam structure DAM disposed between a wavelength conversion layer WCL and a color filter layer CFL and that the color filter layer CFL further includes an overcoat layer OC. Therefore, a description of elements and features identical to those of the above-described embodiment will be omitted, and differences will be described below.

The display device 10 may include a substrate SUB, a light emitting element layer EML, a thin-film encapsulation layer TFEL, the wavelength conversion layer WCL, a filling layer LRF, the dam structure DAM, the color filter layer CFL, and a counter substrate TSUB.

The color filter layer CFL may further include the overcoat layer OC. The overcoat layer OC may cover first through third color filters 350, 360 and 370 and a third color pattern 375. The overcoat layer OC may improve the reliability of bonding to the substrate SUB by planarizing the bottom of the color filter layer CFL.

The overcoat layer OC may be made of an organic material. For example, the overcoat layer OC may include acrylic resin, methacrylate resin, polyisoprene, imide resin, vinyl resin, epoxy resin, urethane resin, cellulose resin, perylene resin, or a combination thereof.

The dam structure DAM may be disposed between the wavelength conversion layer WCL and the color filter layer CFL. The dam structure DAM may be disposed (e.g., directly disposed) on a capping layer 300 of the wavelength conversion layer WCL and may contact (e.g., directly contact) the overcoat layer OC of the color filter layer CFL. The dam structure DAM may maintain a gap between the substrate SUB and the counter substrate TSUB. For example, the dam structure DAM may maintain a gap between the capping layer 300 and the overcoat layer OC.

In an embodiment, the dam structure DAM may be disposed in light emitting areas with a light conversion rate of about 50% or less among multiple light emitting areas. Here, the light conversion rate may refer to the rate at which light emitted from each light emitting element may be converted by the wavelength conversion layer WCL. For example, in a first light emitting area LA1, light emitted from a first light emitting element ED1 may not be converted because a light transmission pattern 230 may be disposed above the first light emitting area LA1. Since the first light emitting area LA1 has a light conversion rate of about 0%, the dam structure DAM may be disposed on the first light emitting area LA1. If the light conversion rate at which light may be converted by a wavelength conversion pattern may be about 50% or less in another light emitting area, the dam structure DAM may also be disposed in the light emitting area.

A light emitting area with a light conversion rate of about 50% or less may be disadvantageous in side luminance. For example, since light emitted from the first light emitting element ED1 of the first light emitting area LA1 may be transmitted and emitted as is through the light transmission pattern 230, the side luminance may be relatively low. On the other hand, light emitted from a second light emitting element ED2 of a second light emitting area LA2 may be converted by first wavelength shifters 245 of a first wavelength conversion pattern 240 and emitted in a Lambertian manner. Therefore, the second light emitting area LA2 may have the same luminance regardless of the angle from which an observer sees, and thus its side luminance may be relatively high.

In the current embodiment, the dam structure DAM has a high refractive index and disperses light to the side as will be described later. Therefore, the dam structure DAM can improve the front side luminance ratio of the first light emitting area LA1 with a light conversion rate of about 50% or less.

The dam structure DAM may overlap the first light emitting area LA1 and may not overlap second and third light emitting areas LA2 and LA3. The dam structure DAM may overlap a non-light emitting area NLA to prevent the light characteristics of the second and third light emitting areas LA2 and LA3 from being affected. The dam structure DAM may overlap a pixel defining layer 150 of the light emitting element layer EML and a bank 180 of the wavelength conversion layer WCL. The dam structure DAM may overlap the first light emitting element ED1 of the light emitting element layer EML, the light transmission pattern 230 of the wavelength conversion layer WCL, and the third color filter 370.

A refractive index of the dam structure DAM may be in a range of about 1.5 to about 2. The dam structure DAM may have a higher refractive index than the filling layer LRF. If the refractive index of the dam structure DAM may be about 1.5 or more, light emitted from the first light emitting area LA1 through the light transmission pattern 230 may be refracted to the side, thereby increasing the front side luminance ratio. If the refractive index of the dam structure DAM may be about 2 or less, a relative reduction in front luminance can be prevented.

A thickness of the dam structure DAM may be in a range of about 0.1 to about 4.5 um. If the thickness of the dam structure DAM may be about 0.1 um or more, light emitted from the first light emitting area LA1 may be refracted to the side, thereby improving the front side luminance ratio. If the thickness of the dam structure DAM may be 4.5 um or less, a gap of the display device 10 can be prevented from increasing. As a result, a thin display device 10 can be implemented.

The area of an upper surface of the dam structure DAM may be about 60% or more of the area of a lower surface. For example, the area of the upper surface of the dam structure DAM may be smaller than, equal to, or larger than the area of the lower surface. In an embodiment, the area of the upper surface of the dam structure DAM may be in a range of about 60 to about 1000% of the area of the lower surface. However, the disclosure may not be limited thereto. The cross-sectional shape of the dam structure DAM may be symmetrical or asymmetrical. For example, the cross-sectional shape of the dam structure DAM may be a regular trapezoid, an inverted trapezoid, or a rectangle.

A taper angle of the dam structure DAM may be in a range of about 20 to about 170 degrees. The taper angle of the dam structure DAM may preferably be in a range of about 40 to about 130 degrees. The area of the upper surface of the dam structure DAM may be in a range of about 60 to about 1000% of the area of the lower surface.

FIGS. 12 through 14 show various example shapes of the dam structure DAM.

Referring to FIG. 12, the area of the upper surface of the dam structure DAM may be in a range of about 60% to less than about 100% of the area of the lower surface of the dam structure DAM. The cross-sectional shape of the dam structure DAM may be a regular trapezoid, and the taper angle (0) may be an acute angle.

Referring to FIG. 13, the area of the upper surface of the dam structure DAM may be 100% of the area of the lower surface. The area of the upper surface of the dam structure DAM and the area of the lower surface of the dam structure DAM may be equal. The cross-sectional shape of the dam structure DAM may be a rectangle, and the taper angle (0) may be a right angle.

Referring to FIG. 14, the area of the upper surface of the dam structure DAM may be in a range of about 100% to about 1000% of the area of the lower surface. The cross-sectional shape of the dam structure DAM may be an inverted trapezoid, and the taper angle (0) may be an obtuse angle.

The filling layer LRF may be disposed on the wavelength conversion layer WCL in areas other than an area where the dam structure DAM may be located. For example, the filling layer LRF may be disposed between portions of the dam structure DAM. The filling layer LRF may overlap the second light emitting area LA2 and the third light emitting area LA3 and may not overlap the first light emitting area LA1 and the non-light emitting area NLA.

Since the filling layer LRF overlaps the second light emitting area LA2 and the third light emitting area LA3, it can totally reflect light emitted from the second light emitting area LA2 and the third light emitting area LA3, thereby improving the front luminance efficiency.

The filling layer LRF may include a filling resin FR and filling particles FP dispersed in the filling resin FR as in the embodiment of FIGS. 5 through 9 described above, or the filling resin FR may include a silicone compound. The filling layer LRF may include vacuum, nitrogen, or an inert gas (e.g., neon). The filling layer LRF may fill spaces between portions of the dam structure DAM with vacuum, nitrogen or an inert gas.

As described above, since the display device 10 according to the embodiment includes the dam structure DAM disposed in a light emitting area with a light conversion ratio of about 50% or less, the front side luminance ratio of the light emitting area can be improved. Since the dam structure DAM may be also disposed in the non-light emitting area NLA, it can act as a spacer that maintains the gap between the substrate SUB and the counter substrate TSUB.

The dam structure DAM can be placed in various ways as long as it overlaps a light emitting area with a light conversion rate of about 50% or less.

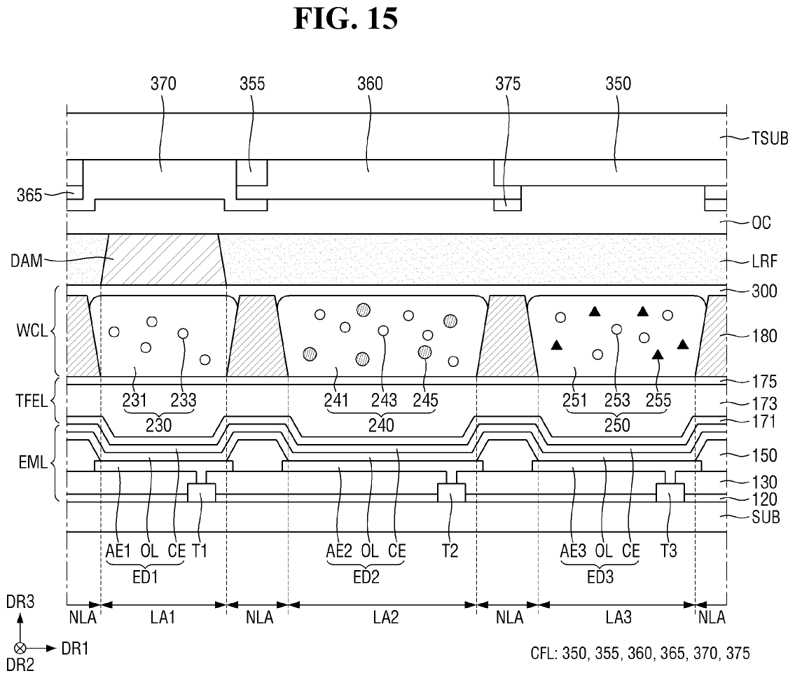

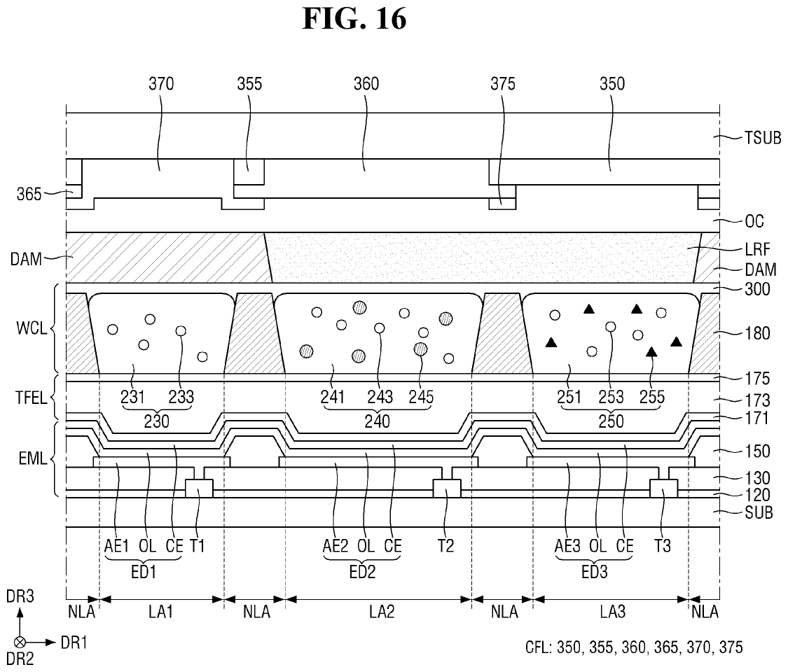

FIGS. 15 and 16 illustrate other examples of the display device 10 according to the embodiment of FIG. 10.

As illustrated in FIG. 15, the dam structure DAM may overlap the first light emitting area LA1 and may not overlap the second light emitting area LA2, the third light emitting area LA3, and the non-light emitting area NLA.

As illustrated in FIG. 16, the dam structure DAM may overlap the first light emitting area LA1 and the non-light emitting area NLA adjacent to the first light emitting area LA1. The dam structure DAM may not overlap the second light emitting area LA2, the third light emitting area LA3, and the non-light emitting area NLA disposed between the second light emitting area LA2 and the third light emitting area LA3.

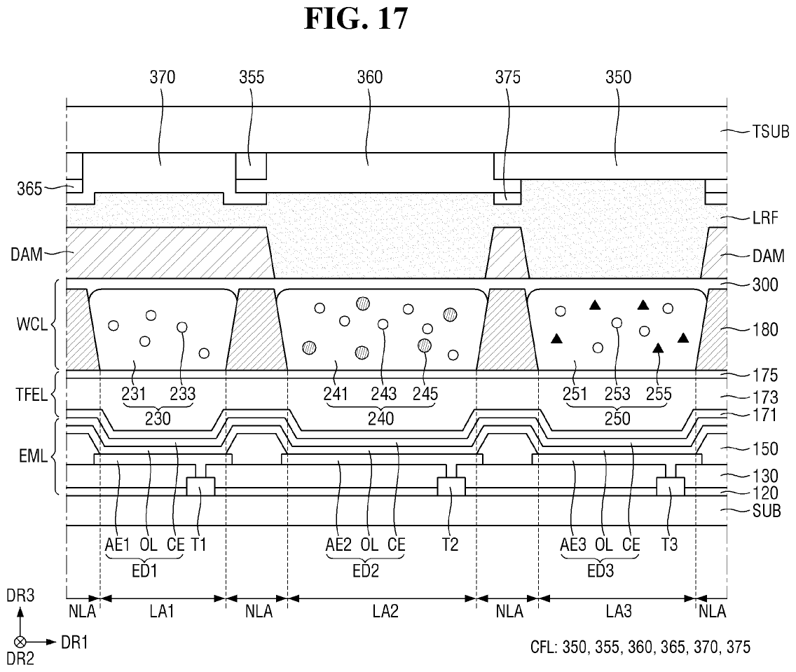

FIG. 17 is a schematic cross-sectional view of a display device according to an embodiment.

Referring to FIG. 17, the current embodiment may be different from the embodiment of FIG. 15 described above in that a filling layer LRF may be disposed between a dam structure DAM and a color filter layer CFL and that an overcoat layer OC may be omitted.

The dam structure DAM may be disposed on a wavelength conversion layer WCL, and the filling layer LRF may be disposed on the wavelength conversion layer WCL and the dam structure DAM. The filling layer LRF may cover the dam structure DAM. Since the dam structure DAM may be disposed on a first light emitting area LA1, a portion of light emitted from the first light emitting area LA1 may reach the dam structure DAM and be refracted to the side, and light passing through the dam structure DAM may reach the filling layer LRF. Since some light may be refracted to the side by the dam structure DAM, even if the filling layer LRF may be disposed on the dam structure DAM, it may not affect an increase in front side luminance ratio.

The dam structure DAM may be spaced apart from the color filter layer CFL and may not contact the color filter layer CFL. Accordingly, since the dam structure DAM may not be affected by a step difference of the color filter layer CFL, the overcoat layer OC of the color filter layer CFL can be omitted.

In the current embodiment, the omission of the overcoat layer OC can simplify the structure and facilitate the process.

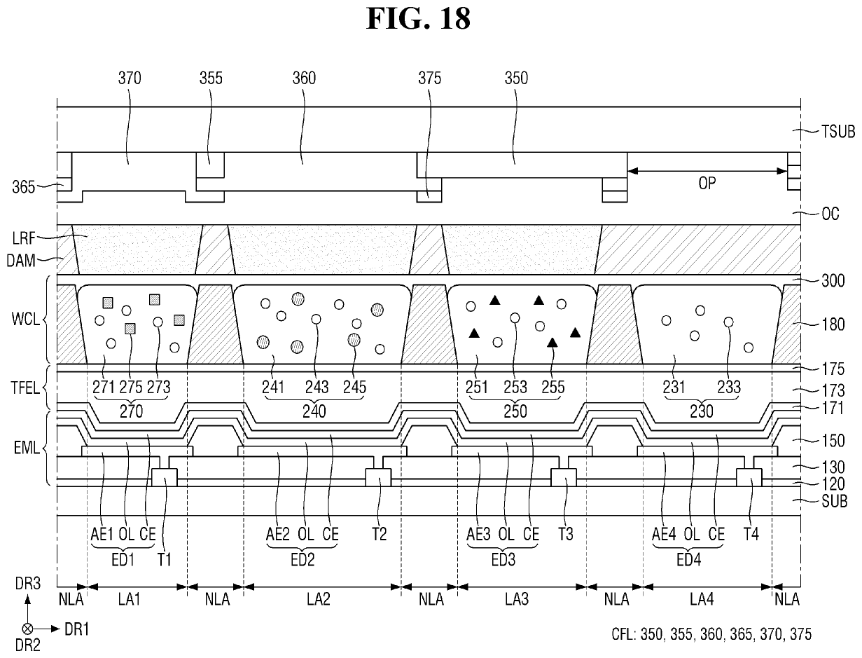

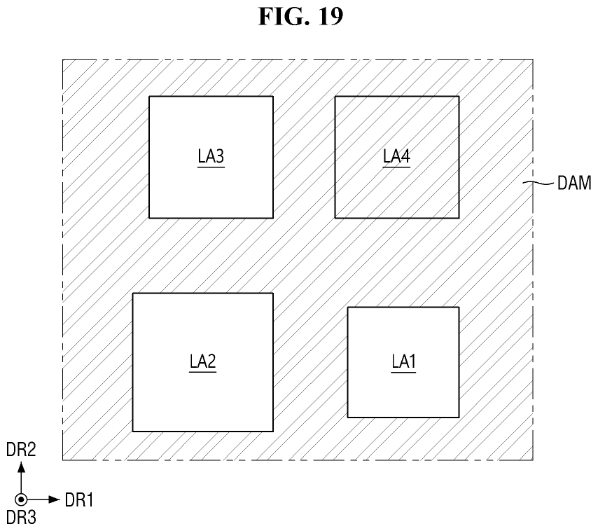

FIG. 18 is a schematic cross-sectional view of a display device according to an embodiment. FIG. 19 is a plan view illustrating light emitting areas of the display device of FIG. 18.

Referring to FIGS. 18 and 19, the current embodiment may be different from the embodiment of FIG. 10 described above in that it further includes a fourth light emitting area LA4 including a fourth switching element T4 and a fourth light emitting element ED4 to emit white light.

The fourth light emitting area LA4 may include the fourth switching element T4 and the fourth light emitting element ED4 on a substrate SUB. First through fourth light emitting elements ED1 through ED4 may emit white light as source light. The white light emitted from a light emitting element layer EML may be output as red light, green light, blue light and white light from a wavelength conversion layer WCL.

Specifically, the wavelength conversion layer WCL may include a third wavelength conversion pattern 270 disposed in a first light emitting area LA1 to convert white light into blue light and a light transmission pattern 230 disposed in the fourth light emitting area LA4 to transmit white light as is.

The third wavelength conversion pattern 270 may be located on a thin-film encapsulation layer TFEL and may overlap the first light emitting area LA1. The third wavelength conversion pattern 270 may convert or shift the peak wavelength of incident light into another specific peak wavelength and output light of the specific peak wavelength. In an embodiment, the third wavelength conversion pattern 270 may convert source light provided from a first light emitting element ED1 into blue light in the range of about 440 to about 480 nm and may output the blue light.

The third wavelength conversion pattern 270 may include a fourth base resin 271 and third wavelength shifters 275 dispersed in the fourth base resin 271 and may further include fourth scatterers 273 dispersed in the fourth base resin 271.

The fourth base resin 271 may be made of a material having high light transmittance. In an embodiment, the fourth base resin 271 may be made of an organic material. The fourth base resin 271 and the first base resin 231 may be made of a same material or the fourth base resin 271 may include at least one of the example materials of the first base resin 231.

The third wavelength shifters 275 may convert or shift the peak wavelength of incident light to another specific peak wavelength. In an embodiment, the third wavelength shifters 275 may convert white source light into blue light having a peak wavelength in the range of 440 to about 480 nm.

The third wavelength shifters 275 may be, for example, quantum dots, quantum rods, or phosphors. A more detailed description of the third wavelength shifters 275 may be substantially the same as or similar to the above description of first wavelength shifters 245 and thus will be omitted.

The fourth scatterers 273 may have a refractive index different from that of the fourth base resin 271 and may form an optical interface with the fourth base resin 271. For example, the fourth scatterers 273 may be light scattering particles. Other details of the fourth scatterers 273 may be substantially the same as or similar to those of second scatterers 243 described above, and thus a detailed description thereof will be omitted.

A portion of source light may be transmitted through the third wavelength conversion pattern 270 without being converted into blue light by the third wavelength shifters 275. However, the portion of the source light which may not be converted into blue light may be blocked by a color filter layer CFL. On the other hand, blue light into which the source light has been converted by the third wavelength conversion pattern 270 may be transmitted through the color filter layer CFL and then emitted to the outside.

The light transmission pattern 230 disposed in the fourth light emitting area LA4 may be the same as the light transmission pattern 230 described above, and thus a description thereof will be omitted. White light emitted from the fourth light emitting element ED4 may be transmitted and emitted as is through the light transmission pattern 230.

The color filter layer CFL may include an opening OP in an area corresponding to the fourth light emitting area LA4. Since the fourth light emitting area LA4 may be an area where white light may be emitted, no color filter may be disposed, and the white light may be emitted as is through the opening OP.

A dam structure DAM may overlap the fourth light emitting area LA4 and may not overlap first through third light emitting areas LA1 through LA3. The dam structure DAM may overlap a non-light emitting area NLA to prevent the light characteristics of the first through third light emitting areas LA1 through LA3 from being affected. The dam structure DAM may overlap the fourth light emitting element ED4 of the light emitting element layer EML, the light transmission pattern 230 of the wavelength conversion layer WCL, and the opening OP.

In an embodiment, the dam structure DAM may be disposed in the fourth light emitting area LA4 with a light conversion rate of about 50% or less among the light emitting areas. Since the light transmission pattern 230 may be disposed above the fourth light emitting area LA4, light emitted from the fourth light emitting element ED4 may not be converted. Thus, the fourth light emitting area LA4 may be disadvantageous in side luminance. However, the dam structure DAM disposed in the fourth light emitting area LA4 disperses light to the side, thereby improving the front side luminance ratio of the fourth light emitting area LA4 with a light conversion rate of about 50% or less.

Hereinafter, simulation examples of the display devices 10 described above will be described.

### <Simulation 1>

A display device 10 including the filling layer LRF illustrated in FIG. 5 was constructed, and the change in white efficiency and front side luminance ratio with respect to the refractive index of the filling layer LRF and BT2020 coverage with respect to the refractive index and thickness of the filling layer LRF were simulated. The filling layer LRF included hollow silica particles.

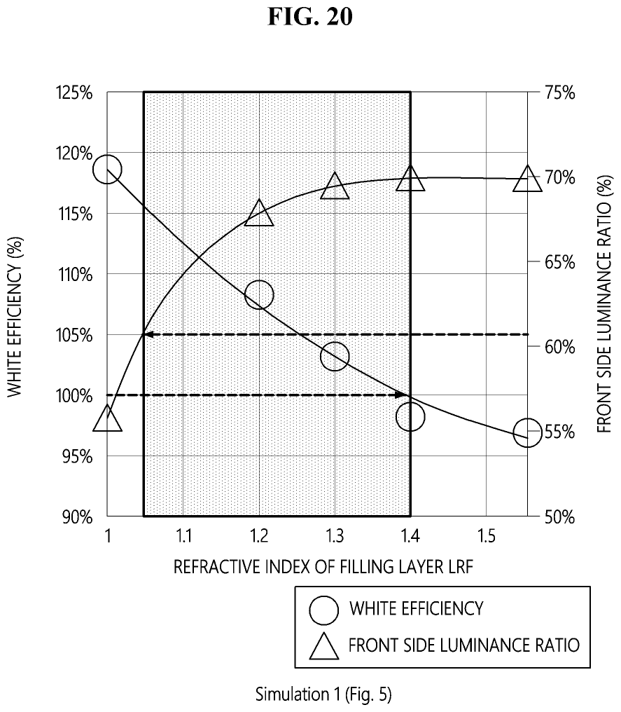

FIG. 20 is a graph illustrating white efficiency and front side luminance ratio with respect to the refractive index of the filling layer LRF. In FIG. 20, the horizontal axis represents the refractive index of the filling layer LRF, the left vertical axis represents the white efficiency, and the right vertical axis represents the front side luminance ratio.

Referring to FIG. 20, the white efficiency decreased as the refractive index of the filling layer LRF increased, and the front side luminance ratio increased as the refractive index of the filling layer LRF increased.

From these results, it can be seen that the filling layer LRF having a refractive index in a range of about 1.05 to about 1.4 can improve the front side luminance ratio of the display device 10 while securing a white efficiency of about 100% or more.

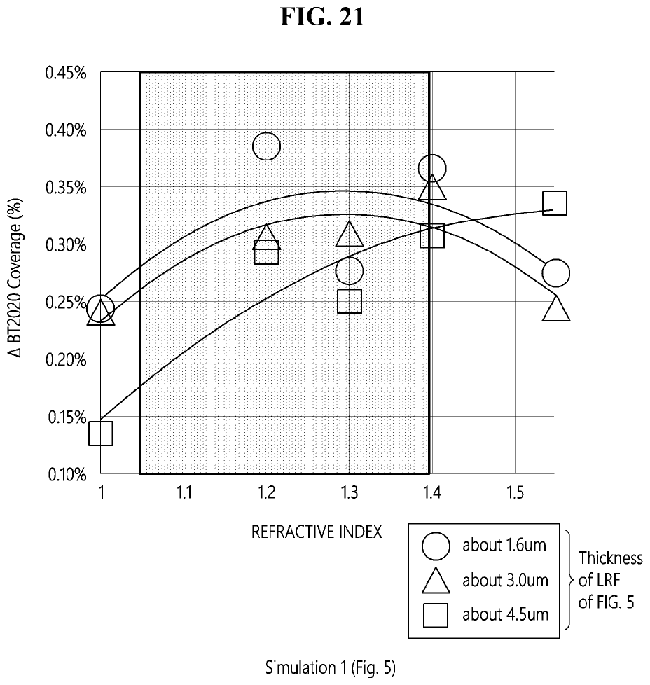

FIG. 21 is a graph illustrating BT2020 coverage with respect to the refractive index and thickness of the filling layer LRF. In FIG. 21, the horizontal axis represents the refractive index of the filling layer LRF, and the vertical axis represents the BT2020 coverage. In FIG. 21, simulations were conducted by varying the thickness of the filling layer LRF to about 1.6 um, about 3.0 um, and about 4.5 um. BT2020 is a next-generation standard color gamut approved by the International Telecommunication Union (ITU).

Referring to FIG. 21, in case that the refractive index of the filling layer LRF was in the range of about 1.05 to about 1.4, the BT2020 coverage increased as the refractive index of the filling layer LRF increased. In case that the thickness of the filling layer LRF was about 1.6 um, about 3.0 um, and about 4.5 um, the BT2020 coverage increased as the refractive index of the filling layer LRF increased.

From these results, it can be seen that the filling layer LRF having a refractive index of in a range of about 1.05 to about 1.4 and a thickness of about 4.5 um or less can improve the BT2020 coverage of the display device 10.

### <Simulation 2>

The display device 10 illustrated in FIG. 5 was constructed, and the refractive index of the filling layer LRF was set to 1. The front side luminance ratios of a red light emitting area LA2, a green light emitting area LA3 and a blue light emitting area LA1 of the display device 10 with respect to angle were simulated, and front luminance and white efficiency were simulated. The front side luminance ratio of the blue light emitting area LA1 with respect to angle was simulated after a dam structure having a refractive index of about 1.5 was provided in the blue light emitting area LA1 as illustrated in FIG. 10, and front luminance and white efficiency were simulated.

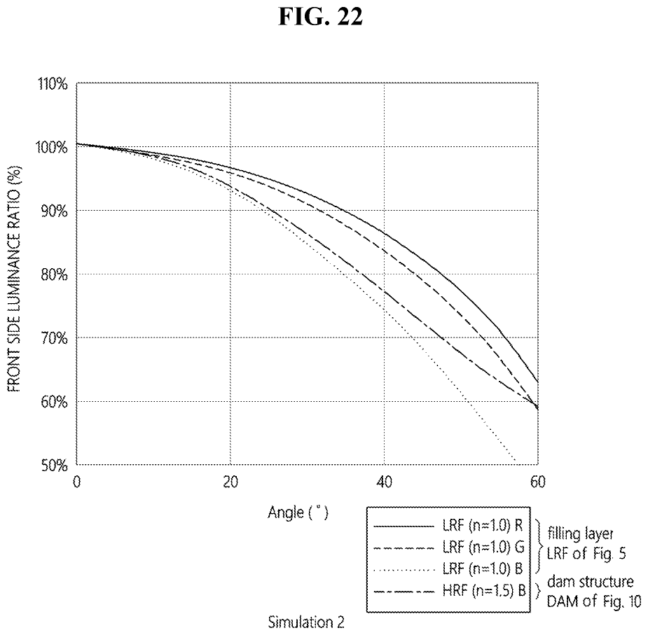

The simulation results of the front side luminance ratio with respect to angle are shown in the graph of FIG. 22, and the simulation results of the front luminance and white efficiency are shown in Table 1 below.

FIG. 22 is a graph illustrating the front side luminance ratio of each light emitting area with respect to angle. In FIG. 22, the horizontal axis represents the angle at which the front side luminance ratio was measured, and the vertical axis represents the front side luminance ratio. LR(n=1.0) R represents the front side luminance ratio of a red light emitting area having a filling layer thereon, LR(n=1.0) G represents the front side luminance ratio of a green light emitting area having the filling layer thereon, LR (n=1.0) B represents the front side luminance ratio of a blue light emitting area having the filling layer thereon, and HR (n=1.5) B represents the front side luminance ratio of a blue light emitting area having a dam structure thereon.

Referring to FIG. 22, in case that a filling layer having a refractive index of 1.0 was provided on the red, green and blue light emitting areas, the front side luminance ratio decreased as the angle increased. In case that a dam structure having a refractive index of about 1.5 was provided on the blue light emitting area, the front side luminance ratio was higher than in case that the filling layer having a refractive index of 1.0 was provided on the blue light emitting area.

In the case of the blue light emitting area, source light emitted from a light emitting element may be transmitted as is through a wavelength conversion layer without being converted by the wavelength conversion layer. Therefore, the front side luminance ratio of the blue light emitting area may be relatively lower than those of the red and green light emitting areas. Hence, it can be seen that a dam structure may be placed on the blue light emitting area to improve the front side luminance ratio by refracting light to the side.

TABLE 1

| | Front luminance of blue | White efficiency of |
|---|---|---|
| Dam structure | light emitting area (%) | display device (%) |
| Non-existent | 106.2 | 108.3 |
| Existent | 98.7 | 107.8 |

Referring to Table 1, in case that the dam structure was placed on the blue light emitting area, the front luminance decreased by about 7.5%, and the white efficiency decreased by about 0.5%, compared with in case that the filling layer was placed on the blue light emitting area.

From these results, it can be seen that in case that the dam structure is placed on the blue light emitting area, the white efficiency may be maintained, but the front efficiency may be reduced. Referring also to FIG. 22, it can be seen that in case that the dam structure is placed on the blue light emitting area, the front side luminance ratio can increase while the white efficiency may be maintained at the same level.

### <Simulation 3>

A display device 10 including the dam structure DAM illustrated in FIG. 10 was constructed, and the white efficiency of the display device 10 with respect to the taper angle of the dam structure DAM was simulated. The white efficiency of the display device 10 including the filling layer LRF illustrated in FIG. 5 was provided as a comparative example (100%). The white efficiency of the display device was provided in a case #1 where the dam structure had a taper angle of about 80 degrees, a case #2 where the dam structure had a taper angle of about 90 degrees, and a case #3 where the dam structure had a taper angle of about 130 degrees.

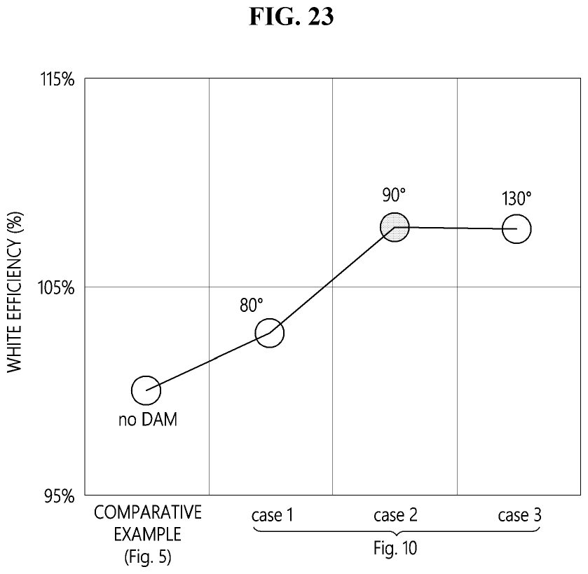

FIG. 23 is a graph illustrating the white efficiency of a display device with respect to the taper angle of a dam structure.

Referring to FIG. 23, the white efficiency was about 102.8% in case that the taper angle of the dam structure was about 80 degrees, about 107.8% in case that the taper angle of the dam structure was about 90 degrees, and about 107.7% in case that the taper angle of the dam structure was about 130 degrees.

From these results, it can be seen that the white efficiency of the display device may be significantly greater than the comparative example in case that the taper angle of the dam structure is about 80 degrees or more.

A display device according to an embodiment includes a filling layer having a low refractive index between a wavelength conversion layer and a color filter layer. Therefore, it may be possible to increase the front side luminance ratio of the display device and prevent a reduction in front luminance efficiency.

A display device according to an embodiment includes a dam structure having a high refractive index in a light emitting area with a light conversion rate of 50% or less. Therefore, it may be possible to improve the front side luminance ratio of the light emitting area and maintain a gap between a substrate and a counter substrate.

However, the effects of the disclosure may not be restricted to the one set forth herein. The above and other effects of the disclosure will become more apparent to one of daily skill in the art to which the disclosure pertains by referencing the claims.

In concluding the detailed description, those skilled in the art will appreciate that many variations and modifications can be made to the embodiments without substantially departing from the principles of the invention. Therefore, the disclosed embodiments of the disclosure may be used in a generic and descriptive sense only and not for purposes of limitation.

What is claimed is:

1. A display device comprising:
a light emitting element layer disposed on a substrate;
a thin-film encapsulation layer disposed on the light emitting element layer;
a wavelength conversion layer disposed on the thin-film encapsulation layer and comprising a bank which defines a plurality of light emitting areas and a non-light emitting area;
a dam structure disposed on the wavelength conversion layer and overlapping at least one of the plurality of light emitting areas;
a filling layer disposed on the wavelength conversion layer and disposed between portions of the dam structure;
a color filter layer disposed on the dam structure; and
a counter substrate disposed on the color filter layer,
wherein the filling layer overlaps ones of the plurality of light emitting areas not overlapping the dam structure.

2. The display device of claim 1, wherein the at least one of the plurality of light emitting areas overlapping the dam structure has a light conversion rate of about 50% or less in the wavelength conversion layer.

3. The display device of claim 1, wherein
the plurality of light emitting areas comprise a first light emitting area which emits blue light, a second light emitting area which emits red light and a third light emitting area which emits green light, and
the dam structure overlaps the first light emitting area.

4. The display device of claim 3, wherein the filling layer overlaps the second light emitting area and the third light emitting area.

5. The display device of claim 1, wherein the dam structure does not overlap the non-light emitting area.

6. The display device of claim 1, wherein the dam structure overlaps portions of the non-light emitting area adjacent to the at least one of the plurality of light emitting areas overlapping the dam structure and does not overlap portions of the non-light emitting area that are spaced apart from the at least one of the plurality of light emitting areas overlapping the dam structure.

7. The display device of claim 1, wherein the dam structure overlaps the non-light emitting area.

8. The display device of claim 1, wherein a refractive index of the dam structure is greater than that of the filling layer.

9. The display device of claim 1, wherein a refractive index of the dam structure is in a range of about 1.5 to about 2.

10. The display device of claim 1, wherein a refractive index of the filling layer is in a range of about 1.05 to about 1.4.

11. The display device of claim 1, wherein a thickness of the dam structure is less than or equal to that of the filling layer.

12. The display device of claim 1, wherein a thickness of the dam structure and a thickness of the filling layer are each in a range of about 0.1 to about 4.5 um.

13. The display device of claim 1, wherein
the color filter layer comprises a plurality of color filters and an overcoat layer covering the plurality of color filters, and
the dam structure and the filling layer contact the overcoat layer.

14. The display device of claim 1, wherein
the wavelength conversion layer comprises a light transmission pattern overlapping the dam structure, and
first and second wavelength conversion patterns overlapping the filling layer.

15. The display device of claim 1, wherein the filling layer overlaps the plurality of light emitting areas and covers the dam structure.

16. The display device of claim 15, wherein
the filling layer contacts the color filter layer, and
the dam structure is spaced apart from the color filter layer.

17. The display device of claim 1, wherein the filling layer comprises an arrangement selected from a plurality of filling particles dispersed in a filling resin, a silicone compound, and at least one of a vacuum, nitrogen gas and an inert gas.

18. A display device comprising:
a light emitting element layer disposed on a substrate;
a thin-film encapsulation layer disposed on the light emitting element layer;
a wavelength conversion layer disposed on the thin-film encapsulation layer and comprising a bank which defines a plurality of light emitting areas and a non-light emitting area;
a dam structure disposed on the wavelength conversion layer and overlapping ones of the plurality of light emitting areas having a light conversion rate of about 50% or less in the wavelength conversion layer;
a filling layer disposed on the wavelength conversion layer and disposed between portions of the dam structure;
a color filter layer disposed on the dam structure; and
a counter substrate disposed on the color filter layer.

19. The display device of claim 18, wherein
the plurality of light emitting areas comprise a first light emitting area which emits blue light, a second light emitting area which emits red light and a third light emitting area which emits green light, and
the dam structure overlaps the first light emitting area.

20. The display device of claim 18, wherein
the plurality of light emitting areas comprise a first light emitting area which emits blue light, a second light emitting area which emits red light, a third light emitting area which emits green light, and a fourth light emitting area which emits white light, and
the dam structure overlaps the fourth light emitting area.

21. The display device of claim 18, wherein a taper angle of the dam structure is in a range of about 20 to about 170 degrees.

22. The display device of claim 18, wherein an area of an upper surface of the dam structure is in a range of about 60 to about 1000% of the area of a lower surface of the dam structure.

23. A display device comprising:
a light emitting element layer disposed on a substrate;
a thin-film encapsulation layer disposed on the light emitting element layer;
a wavelength conversion layer disposed on the thin-film encapsulation layer;
a filling layer disposed on the wavelength conversion layer;
a color filter layer disposed on the filling layer; and
a counter substrate disposed on the color filter layer,
wherein a refractive index of the filling layer is in a range of about 1.05 to about 1.4, and a thickness of the filling layer is in a range of about 0.1 to about 4.5 um.

24. The display device of claim 23, wherein the filling layer is disposed between the wavelength conversion layer and the color filter layer and contacts each of the wavelength conversion layer and the color filter layer.

25. The display device of claim 23, wherein the filling layer comprises a silicone compound or a plurality of filling particles dispersed in a filling resin.
